(19) United States
(12) Patent Application Publication
(10) Pub. No.: US 2025/0365941 A1
(43) Pub. Date: Nov. 27, 2025

(54) SEMICONDUCTOR DEVICE

(71) Applicant: Samsung Electronics Co., Ltd., Suwon-si (KR)

(72) Inventors: Hyungki Cho, Suwon-si (KR); Minjeong Choi, Suwon-si (KR)

(21) Appl. No.: 18/965,037

(22) Filed: Dec. 2, 2024

(30) Foreign Application Priority Data
May 23, 2024 (KR) 10-2024-0067223

(51) Int. Cl. H10B 12/00

(52) U.S. Cl. CPC H10B 12/488; H10B 12/315; H10B 12/482

(57) ABSTRACT

A semiconductor device may include a substrate, first and second data storage patterns on the substrate, a first storage contact on the first data storage pattern, a second storage contact on the second data storage pattern, a first word line that overlaps the first storage contact, a second word line that overlaps the second storage contact, a first insulating pattern between the first and second word lines, a first channel pattern on the first storage contact, a second channel pattern on the second storage contact, a bit line on the first and second channel patterns, and a gate insulating pattern between the first word line and the first channel pattern, between the second word line and the second channel pattern, between the first word line and the bit line, between the second word line and the bit line, and between the first insulating pattern and the bit line.

### CROSS-REFERENCE TO RELATED APPLICATIONS

This application claims priority to and the benefit of Korean Patent Application No. 10-2024-0067223, filed in the Korean Intellectual Property Office on May 23, 2024, the entire contents of which are incorporated herein by reference.

### BACKGROUND OF THE INVENTION

The present disclosure relates to a semiconductor device.

A semiconductor is a material belonging to an intermediate region between a conductor and an insulator, and refers to a material that conducts electricity under a predetermined condition. Various semiconductor devices can be manufactured by using such a semiconductor material, and for example, a memory device and the like can be manufactured. Such a semiconductor device may be used in various electronic devices.

In accordance with miniaturization and high integration trends of electronic devices, it is helpful to finely form patterns constituting a semiconductor device. As a width of these fine patterns gradually decreases, process difficulty may increase and a defect rate of semiconductor devices may increase.

### SUMMARY OF THE INVENTION

Example embodiments of the present disclosure provide a semiconductor device with improved performance and reliability.

According to some aspects of the present disclosure, a semiconductor device is provided that includes: a substrate; a first data storage pattern and a second data storage pattern spaced apart from each other along a first direction on the substrate; a first storage contact electrically connected to the first data storage pattern; a second storage contact electrically connected to the second data storage pattern; a first word line that extends along a second direction intersecting the first direction and overlaps the first storage contact in a third direction perpendicular to the first and second directions; a second word line that extends along the second direction and overlaps the second storage contact in the third direction; a first insulating pattern between the first word line and the second word line; a first channel pattern electrically connected to the first storage contact; a second channel pattern electrically connected to the second storage contact; a bit line that is electrically connected to the first channel pattern and the second channel pattern and extends along the first direction; and a gate insulating pattern between the first word line and the first channel pattern, between the second word line and the second channel pattern, between the first word line and the bit line, between the second word line and the bit line, and between the first insulating pattern and the bit line.

According to some aspects of the present disclosure, a semiconductor device is provided that includes: a substrate; a first data storage pattern and a second data storage pattern spaced apart from each other along a first direction on the substrate; a first storage contact in contact with an upper surface of the first data storage pattern; a second storage contact in contact with an upper surface of the second data storage pattern; a first word line spaced apart from the first storage contact and extending along a second direction intersecting the first direction; a second word line spaced apart from the second storage contact and extending along the second direction; a first insulating pattern between the first word line and the second word line; a gate insulating pattern on a side surface and an upper surface of the first word line, an upper surface of the first insulating pattern, and an upper surface and a side surface of the second word line; a first channel pattern spaced apart from the first word line, with the gate insulating pattern therebetween, and electrically connected to the first storage contact; a second channel pattern spaced apart from the second word line, with the gate insulating pattern therebetween, and electrically connected to the second storage contact; and a bit line that contacts an upper surface and a side surface of the first channel pattern and an upper surface and a side surface of the second channel pattern, the bit line extending along the first direction.

According to some aspects of the present disclosure, a semiconductor device is provided that includes: a substrate; a first data storage pattern and a second data storage pattern spaced apart from each other along a first direction on the substrate; a first storage contact in contact with an upper surface of the first data storage pattern; a second storage contact in contact with an upper surface of the second data storage pattern; a first word line spaced apart from the first storage contact and extending along a second direction intersecting the first direction; a second word line spaced apart from the second storage contact and extending along the second direction; a first insulating pattern between the first word line and the second word line; a gate insulating pattern on a side surface and an upper surface of the first word line, an upper surface of the first insulating pattern, and an upper surface and a side surface of the second word line; a first channel pattern spaced apart from the first word line, with the gate insulating pattern therebetween, and on an upper surface and a side surface of the first storage contact; a second channel pattern spaced apart from the second word line, with the gate insulating pattern therebetween, and on an upper surface and a side surface of the second storage contact; and a bit line electrically connected to the first channel pattern and the second channel pattern and extending along the first direction.

According to example embodiments of the present disclosure, performance and reliability of semiconductor devices may be improved.

### BRIEF DESCRIPTION OF THE DRAWINGS

FIG. 1 illustrates a top plan view showing a semiconductor device according to some embodiments.

FIG. 2 illustrates a cross-sectional view taken along a line A-A′ of FIG. 1.

FIG. 3 illustrates a cross-sectional view taken along a line B-B′ of FIG. 1.

FIGS. 4 to 54 each illustrate a process plan view or process cross-sectional view sequentially illustrating a manufacturing method of a semiconductor device according to some embodiments.

FIGS. 55 to 59 each illustrate a cross-sectional view showing a semiconductor device according to some embodiments.

### DETAILED DESCRIPTION

The present disclosure will be described more fully hereinafter with reference to the accompanying drawings, in which example embodiments of the disclosure are shown. As those skilled in the art will understand, the described embodiments may be modified in various different ways without departing from the scope of the present disclosure.

To clearly describe the inventive concepts, parts that are irrelevant to the description may be omitted, and like numerals refer to like or similar components throughout the specification.

Further, sizes and thicknesses of constituent members shown in the accompanying drawings are given for better understanding and ease of description, but the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. When an element is referred to as being “directly on” another element, there are no intervening elements present.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Further, throughout the specification, the phrase “in a plan view” means when an object portion is viewed from above, and the phrase “in a cross-sectional view” means when a cross-section taken by vertically cutting an object portion is viewed from the side.

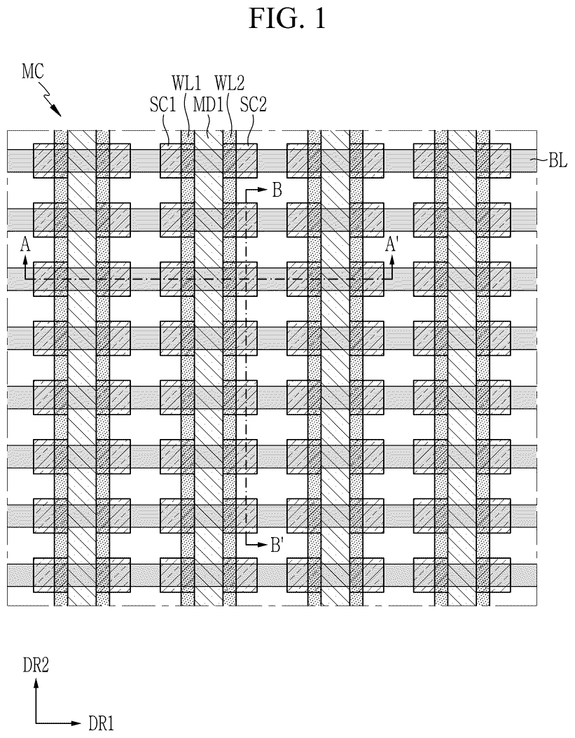

Hereinafter, a semiconductor device according to some embodiments will be described with reference to FIGS. 1 to 3.

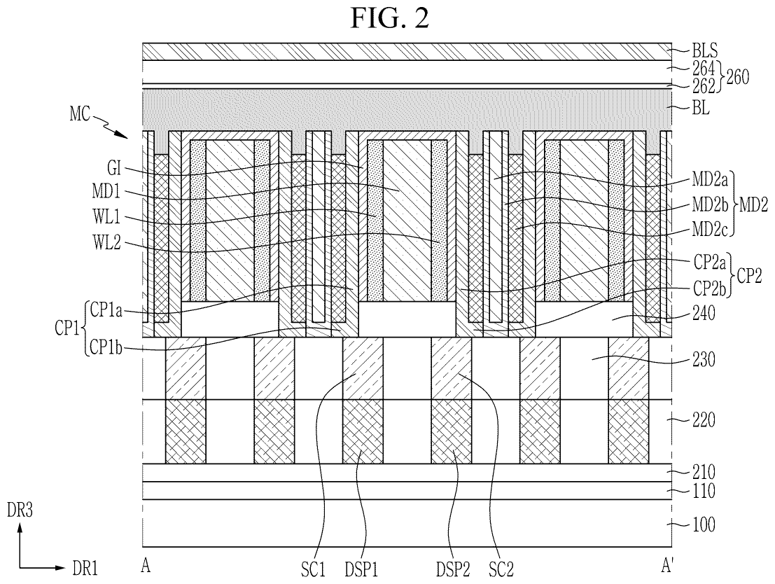

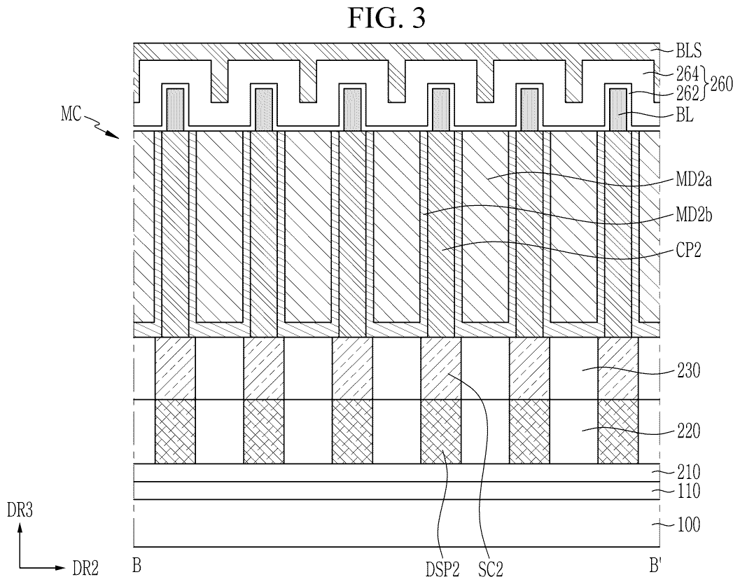

FIG. 1 illustrates a top plan view showing a semiconductor device according to some embodiments. FIG. 2 illustrates a cross-sectional view taken along a line A-A′ of FIG. 1. FIG. 3 illustrates a cross-sectional view taken along a line B-B′ of

FIG. 1.

As shown in FIGS. 1 to 3, the semiconductor device according to some embodiments may include a substrate 100 and a memory cell MC positioned on the substrate 100. The memory cell MC may be formed to include a memory cell of a volatile memory device, a memory cell of a non-volatile memory device, etc. For example, the memory cell MC may be made of a dynamic random access memory (DRAM). A plurality of unit memory cells for storing information may be regularly and repeatedly arranged on the substrate 100. One unit memory cell may include at least one transistor and at least one capacitor.

The substrate 100 may include a semiconductor material. For example, the substrate 100 may include a group IV semiconductor, a group III-V compound semiconductor, a group II-VI compound semiconductor, and the like. For example, the substrate 100 may include a semiconductor such as silicon (Si) or germanium (Ge), or a compound semiconductor such as SiGe, SiC, GaAs, InAs, or InP. However, a material included in the substrate 100 is not limited thereto, and may be variously changed. The substrate 100 may have an upper surface parallel to a first direction DR1 and a second direction DR2, and may have a thickness parallel to a third direction DR3, which is perpendicular to the first direction DR1 and the second direction DR2.

Although not shown, a driving circuit that generates signals for driving the memory cell MC and a wire that transmits these signals may be positioned on the substrate 100. For example, the substrate 100 may include a core region and a peripheral region, and a sense amplifier, a subword line driver, etc. may be positioned in the core region. A row decoder, a column decoder, etc. may be positioned in the peripheral region.

The substrate 100 and the memory cell MC may be bonded using a dielectric bonding method. A first bonding insulating layer 110 and a second bonding insulating layer 210 may be sequentially positioned on the substrate 100, and the second bonding insulating layer 210 may be bonded to the first bonding insulating layer 110. After positioning the first bonding insulating layer 110 positioned on the substrate 100 and the second bonding insulating layer 210 positioned on the memory cell MC to face each other, the first bonding insulating layer 110 and the second bonding insulating layer 210 may be bonded. In this case, circuits and wires positioned in the core/peripheral region and the memory cell MC may be connected by a contact member extending through the memory cell MC.

However, the present disclosure is not limited thereto, and a positional relationship between the substrate 100 and the memory cell MC may change in various ways. Additionally, circuits and wiring positioned in the core/peripheral region and the memory cell MC may be connected by hybrid bonding.

The memory cell MC may include a first data storage pattern DSP1 and a second data storage pattern DSP2, a first storage contact SC1 and a second storage contact SC2 connected to the first data storage pattern DSP1 and the second data storage pattern DSP2, respectively, a first word line WL1 and a second word line WL2 positioned on the first storage contact SC1 and the second storage contact SC2, respectively, a first channel pattern CP1 and a second channel pattern CP2 respectively connected to the first storage contact SC1 and the second storage contact SC2, and a bit line BL connected to the first channel pattern CP1 and the second channel pattern CP2.

The first data storage pattern DSP1 and the second data storage pattern DSP2 may each be a capacitor. The first data storage pattern DSP1 and the second data storage pattern DSP2 may each include a first capacitor electrode, a second capacitor electrode, and a dielectric layer positioned between the first capacitor electrode and the second capacitor electrode. The first capacitor electrode may be in contact with the first storage contact SC1 and the second storage contact SC2, and may be electrically connected to the first storage contact SC1 and the second storage contact SC2. The first capacitor electrode of the first data storage pattern DSP1 may be connected to the first storage contact SC1, and the first capacitor electrode of the second data storage pattern DSP2 may be connected to the second storage contact SC2. The first data storage pattern DSP1 may be connected to the first channel pattern CP1 through the first storage contact SC1, and the second data storage pattern DSP2 may be connected to the second channel pattern CP2 through the second storage contact SC2. According to some embodiments, the semiconductor device may include a plurality of first data storage patterns DSP1 and a plurality of second data storage patterns DSP2. First capacitor electrodes of the first data storage patterns DSP1 and the second data storage patterns DSP2 are separated from each other. A same voltage may be applied to second capacitor electrodes of the first data storage patterns DSP1 and the second data storage patterns DSP2, and may be integrated with each other. Dielectric layers of the first data storage patterns DSP1 and the second data storage patterns DSP2 may be formed as one body.

However, the present disclosure is not limited thereto, and the first data storage pattern DSP1 and the second data storage pattern DSP2 may be variable resistance patterns that can be switched into two resistance states by electrical pulses applied to a memory element. For example, the first data storage pattern DSP1 and the second data storage pattern DSP2 may include a phase-change material, whose crystal state changes depending on an amount of current, a perovskite compound, a transition metal oxide, a magnetic material, a ferromagnetic material, or an antiferromagnetic material.

The first data storage pattern DSP1 and the second data storage pattern DSP2 may be positioned spaced apart from each other along the first direction DR1 on the substrate 100. When the first data storage pattern DSP1 and the second data storage pattern DSP2 are made of capacitors, this indicates that first capacitors are spaced apart, and dielectric layers and second capacitors may be connected to each other. The first data storage pattern DSP1 and the second data storage pattern DSP2 may be positioned on the second bonding insulating layer 210.

According to some embodiments, the semiconductor device may include a plurality of first data storage patterns DSP1 and a plurality of second data storage patterns DSP2. The first data storage pattern DSP1 and the second data storage pattern DSP2 may be alternately positioned along the first direction DR1. The first data storage patterns DSP1 may be spaced apart from each other along the second direction DR2. The second data storage patterns DSP2 may be spaced apart from each other along the second direction DR2. That is, a row formed of the first data storage patterns DSP1 and a row formed of the second data storage patterns DSP2 may be alternately and repeatedly positioned.

According to some embodiments, the semiconductor device may further include a first interlayer insulating layer 220 disposed on the substrate 100. The first interlayer insulating layer 220 may be positioned on the second bonding insulating layer 210, and may be disposed between the first data storage pattern DSP1 and the second data storage pattern DSP2. The first interlayer insulating layer 220 may be disposed between the first data storage patterns DSP1 and between the second data storage patterns DSP2. In a plan view, the first data storage pattern DSP1 may be surrounded by the first interlayer insulating layer 220, and the second data storage pattern DSP2 may be surrounded by the first interlayer insulating layer 220.

The first interlayer insulating layer 220 may include an insulating material. For example, the first interlayer insulating layer 220 may include a silicon oxide, a silicon nitride, a silicon oxynitride, etc.

The first storage contact SC1 and the second storage contact SC2 may be positioned on the first data storage pattern DSP1 and the second data storage pattern DSP2, respectively. The first storage contact SC1 may be positioned on the first data storage pattern DSP1, and may be electrically connected to the first data storage pattern DSP1. A lower surface of the first storage contact SC1 may contact an upper surface of the first data storage pattern DSP1. The first storage contact SC1 may have a width similar to that of the first data storage pattern DSP1. The second storage contact SC2 may be positioned on the second data storage pattern DSP2, and may be electrically connected to the second data storage pattern DSP2. A lower surface of the second storage contact SC2 may contact an upper surface of the second data storage pattern DSP2. The second storage contact SC2 may have a width similar to that of the second data storage pattern DSP2. The first storage contact SC1 and the second storage contact SC2 may respectively overlap the first data storage pattern DSP1 and the second data storage pattern DSP2 in the third direction DR3. As used herein, “an element A overlaps an element B in a direction X” (or similar language) means that there is at least one straight line that extends in the direction X and intersects both the elements A and B. In some cases, the first storage contact SC1 and the second storage contact SC2 may at least partially overlap the first interlayer insulating layer 220.

The first storage contact SC1 and the second storage contact SC2 may have substantially a same disposition as the first data storage pattern DSP1 and the second data storage pattern DSP2, respectively. The first storage contact SC1 and the second storage contact SC2 may be positioned spaced apart from each other along the first direction DR1 on the substrate 100. A distance between the first storage contact SC1 and the second storage contact SC2 may be similar to a distance between the first data storage pattern DSP1 and the second data storage pattern DSP2. Numbers of first storage contacts SC1 and second storage contacts SC2 may correspond to numbers of first data storage patterns DSP1 and second data storage patterns DSP2, respectively. The number of first storage contacts SC1 may be substantially equal to the number of first data storage patterns DSP1. The number of second storage contacts SC2 may be substantially equal to the number of second data storage patterns DSP2.

The semiconductor device according to some embodiments may include a plurality of first storage contacts SC1 and a plurality of second storage contacts SC2. The first storage contact SC1 and the second storage contact SC2 may be alternately positioned along the first direction DR1. The first storage contacts SC1 may be positioned to be spaced apart from each other along the second direction DR2. The second storage contacts SC2 may be spaced apart from each other along the second direction DR2. That is, a row formed of the first storage contacts SC1 and a row formed of the second storage contacts SC2 may be alternately and repeatedly positioned.

The first storage contact SC1 and the second storage contact SC2 may include a doped polysilicon, a metal, a conductive metal nitride, a conductive metal oxide, or a combination thereof. For example, the first storage contact SC1 and the second storage contact SC2 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present disclosure is not limited thereto.

According to some embodiments, the semiconductor device may further include a second interlayer insulating layer 230 disposed on the substrate 100. The second interlayer insulating layer 230 may be positioned on the first interlayer insulating layer 220 and may be positioned between the first storage contact SC1 and the second storage contact SC2. The second interlayer insulating layer 230 may be positioned between the first storage contacts SC1 and between the second storage contacts SC2. In a plan view, the first storage contact SC1 may be surrounded by the second interlayer insulating layer 230, and the second storage contact SC2 may be surrounded by the second interlayer insulating layer 230.

The second interlayer insulating layer 230 may include an insulating material. For example, the second interlayer insulating layer 230 may include a silicon oxide, a silicon nitride, a silicon oxynitride, etc.

According to some embodiments, the semiconductor device may further include a storage capping pattern 240 positioned on the first storage contact SC1 and the second storage contact SC2. The storage capping pattern 240 may be on (e.g., may cover) portions of upper surfaces of the first and second storage contacts SC1 and SC2, and may not be on remaining portions. The storage capping pattern 240 may be on (e.g., may cover) an upper surface of the second interlayer insulating layer 230 positioned between the first storage contact SC1 and the second storage contact SC2. That is, the storage capping pattern 240 may continuously be on (e.g., may continuously cover) a portion of the first storage contact SC1, the second interlayer insulating layer 230, and a portion of the second storage contact SC2. A row formed of the first storage contacts SC1 and a row formed of the second storage contacts SC2 may form a pair of storage contact rows. The storage capping pattern 240 may overlap the pair of storage contact rows in the third direction DR3, and may extend along the second direction DR2. The storage capping pattern 240 may not cover between one pair of storage contact rows and another pair of adjacent storage contact rows. A plurality of storage capping patterns 240 may be positioned spaced apart from each other along the first direction DR1.

The storage capping patterns 240 may include an insulating material. For example, the storage capping patterns 240 may include a silicon oxide, a silicon nitride, a silicon oxynitride, etc. The storage capping patterns 240 may include a same material as the second interlayer insulating layer 230. In this case, an interface between the storage capping pattern 240 and the second interlayer insulating layer 230 may not be visible. That is, the storage capping pattern 240 and the second interlayer insulating layer 230 may be formed as one body.

The first word line WL1 and the second word line WL2 may be positioned on the storage capping pattern 240. The first word line WL1 and the second word line WL2 may extend along the second direction DR2. The first word line WL1 and the second word line WL2 may be spaced apart in the first direction DR1. The first word line WL1 may overlap the first storage contact SC1 in the third direction DR3. The first word line WL1 may overlap the row formed of the first storage contacts SC1 spaced apart along the second direction DR2. The second word line WL2 may overlap the second storage contact SC2 in the third direction DR3. The second word line WL2 may overlap the row formed of the second storage contacts SC2 spaced apart along the second direction DR2. Numbers of first word lines WL1 and second word lines WL2 may correspond to numbers of rows of first and second storage contacts SC1 and SC2, respectively. The number of first word lines WL1 may be substantially equal to the number of rows of first storage contact SC1. The number of second word lines WL2 may be substantially equal to the number of rows of second storage contact SC2.

A width of the first word line WL1 in the first direction DR1 may be smaller than a width of the first storage contact SC1 in the first direction DR1. The width of the first word line WL1 in the first direction DR1 may be smaller than the length of the first word line WL1 in the third direction DR3. A width of the second word line WL2 in the first direction DR1 may be smaller than a width of the second storage contact SC2 in the first direction DR1. The width of the second word line WL2 in the first direction DR1 may be smaller than the length of the second word line WL2 in the third direction DR3.

The first word line WL1 and the second word line WL2 may include a doped polysilicon, a metal, a conductive metal nitride, a conductive metal oxide, or a combination thereof. For example, the first word line WL1 and the second word line WL2 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present disclosure is not limited thereto.

According to some embodiments, the semiconductor device may further include a first insulating pattern MD1 positioned between the first word line WL1 and the second word line WL2. The first word line WL1 and the second word line WL2 may be positioned at opposite sides of the first insulating pattern MD1. For example, the first word line WL1 may be positioned to a left side of the first insulating pattern MD1, and the second word line WL2 may be positioned to a right side of the first insulating pattern MD1. A left-hand side of the first insulating pattern MD1 may contact the first word line WL1, and a right-hand side of the first insulating pattern MD1 may contact the second word line WL2. The first insulating pattern MD1 may be positioned on the storage capping pattern 240.

The width of the first insulating pattern MD1 in the first direction DR1 may be smaller than the length of the first word line WL1 in the third direction DR3. The width of the first insulating pattern MD1 along the first direction DR1 may be greater than the width of the first word line WL1 along the first direction DR1. The width of the first insulating pattern MD1 along the first direction DR1 may be greater than the width of the second word line WL2 along the first direction DR1. A length of the first insulating pattern MD1 along the third direction DR3 may be similar to the length of the first word line WL1 along the third direction DR3. A length of the first insulating pattern MD1 along the third direction DR3 may be similar to the length of the second word line WL2 along the third direction DR3. An upper surface of the first insulating pattern MD1 may be positioned at substantially a same level as an upper surface of the first word line WL1 and an upper surface of the second word line WL2. For example, the upper surface of the first insulating pattern MD1 may be coplanar with the upper surface of the first word line WL1 and the upper surface of the second word line WL2. A lower surface of the first insulating pattern MD1 may be positioned at substantially a same level as a lower surface of the first word line WL1 and a lower surface of the second word line WL2. For example, the lower surface of the first insulating pattern MD1 may be coplanar with the lower surface of the first word line WL1 and the lower surface of the second word line WL2. The first insulating pattern MD1 may extend along the second direction DR2. A length of the first insulating pattern MD1 along the second direction DR2 may be similar to the length of the first word line WL1 along the second direction DR2. A length of the first insulating pattern MD1 along the second direction DR2 may be similar to the length of the second word line WL2 along the second direction DR2. According to some embodiments, the semiconductor device may include a plurality of first insulating patterns MD1. The first insulating patterns MD1 may be positioned to be spaced apart from each other along the first direction DR1. As used herein, the term “level” refers to a height or distance in the third direction DR3 (e.g., a vertical direction) from the upper surface of the substrate 100.

The first insulating pattern MD1 is positioned between the first word line WL1 and the second word line WL2 that constitute one word line pair, and may not be positioned between adjacent word line pairs. A number of first insulating patterns MD1 may correspond to a number of word line pairs. A number of first insulating patterns MD1 may be substantially equal to the number of word line pairs. The number of first insulating patterns MD1 may be substantially equal to a number of first word lines WL1. The number of first insulating patterns MD1 may be substantially equal to a number of second word lines WL2. The number of first insulating patterns MD1 may correspond to a number of storage capping patterns 240.

The first insulating pattern MD1 may include an insulating material. The first insulating pattern MD1 may include a low dielectric constant (low-k) material that has a lower dielectric constant than silicon oxide. For example, a low dielectric constant material may include at least one of a flowable oxide (FOX), a torene silazene (TOSZ), an undoped silicate glass (USG), a borosilicate glass (BSG), a phosphosilicate glass (PSG), a borophosphosilicate glass (BPSG), a plasma enhanced tetra ethyl ortho silicate (PETEOS), a fluoride silicate glass (FSG), a carbon doped silicon oxide (CDO), xerogel, aerogel, amorphous fluorinated carbon, an organo silicate glass (OSG), parylene, bis-benzocyclobutenes (BCB), SiLK, polyimide, or a porous polymeric material. However, the present disclosure is not limited thereto, and the first insulating pattern MD1 may include at least one of a silicon oxide, a silicon nitride, or a silicon oxynitride.

According to some embodiments, the semiconductor device may further include a gate insulating pattern GI positioned on the first word line WL1 and the second word line WL2. The gate insulating pattern GI may be positioned on the first insulating pattern MD1. The gate insulating pattern GI may be continuously formed to be on (e.g., to cover) one side surface and an upper surface of the first word line WL1, an upper surface of the first insulating pattern MD1, and an upper surface and one side surface of the second word line WL2. For example, an upper surface and a left-hand side of the first word line WL1 may be covered by the gate insulating pattern GI, and a right-hand side of the first word line WL1 may be covered by the first insulating pattern MD1. The upper and left-hand sides of the first word line WL1 may be in contact with the gate insulating pattern GI, and the right-hand side of the first word line WL1 may be in contact with the first insulating pattern MD1. However, the present disclosure is not limited thereto, and another layer may be further positioned between the first word line WL1 and the gate insulating pattern GI and/or between the first word line WL1 and the first insulating pattern MD1. An upper surface and a right-hand side of the second word line WL2 may be covered by the gate insulating pattern GI, and a left-hand side of the second word line WL2 may be covered by the first insulating pattern MD1. The upper and right-hand sides of the second word line WL2 may be in contact with the gate insulating pattern GI, and the left-hand side of the second word line WL2 may be in contact with the first insulating pattern MD1. However, the present disclosure is not limited thereto, and another layer may be further positioned between the second word line WL2 and the gate insulating pattern GI and/or between the second word line WL2 and the first insulating pattern MD1.

The gate insulating pattern GI may be positioned on the storage capping pattern 240. On the storage capping pattern 240, the gate insulating pattern GI, the first word line WL1, the first insulating pattern MD1, the second word line WL2, and the gate insulating pattern GI may be positioned sequentially along the first direction DR1. The width of the storage capping pattern 240 along the first direction DR1 may be similar to a sum of the widths of the gate insulating pattern GI, the first word line WL1, the first insulating pattern MD1, the second word line WL2, and the gate insulating pattern GI in the first direction DR1.

The gate insulating pattern GI may include a silicon oxide, a silicon nitride, a silicon oxynitride, a high-k material having a higher dielectric constant than silicon oxide, or a combination thereof. For example, a high dielectric constant material may include at least one of ZrO₂, ZrON, HfO₂, HfON, ZrSiOx, ZrSiON, HfSiOx, HfSiON, HfZrO₂, ZrHfSiOx, La₂O₃, LaAlO, TaO, TiO, BaSrTiO, BaTIO, SrTiO, YO, Al₂O₃, PbScTaO, or a combination thereof.

The first channel pattern CP1 and the second channel pattern CP2 may be positioned at opposite sides of the first insulating pattern MD1. For example, the first channel pattern CP1 may be positioned to a left side of the first insulating pattern MD1, and the second channel pattern CP2 may be positioned at a right side of the first insulating pattern MD1. The first channel pattern CP1 may be adjacent to the first word line WL1. The first channel pattern CP1 may be positioned at a left side of the first word line WL1. The gate insulating pattern GI may be positioned between the first channel pattern CP1 and the first word line WL1. The first channel pattern CP1 may be spaced apart from the first word line WL1 with the gate insulating pattern GI provided therebetween. The second channel pattern CP2 may be adjacent to the second word line WL2. The second channel pattern CP2 may be positioned at a right side of the second word line WL2. The gate insulating pattern GI may be positioned between the second channel pattern CP2 and the second word line WL2. The second channel pattern CP2 may be spaced apart from the second word line WL2 with the gate insulating pattern GI provided therebetween. The upper surface of the gate insulating pattern GI, the upper surface of the first channel pattern CP1, and the upper surface of the second channel pattern CP2 may be positioned at substantially a same level. For example, the upper surface of the gate insulating pattern GI, the upper surface of the first channel pattern CP1, and the upper surface of the second channel pattern CP2 may be coplanar with each other.

The storage capping pattern 240 may be positioned between the first channel pattern CP1 and the second channel pattern CP2. For example, the first channel pattern CP1 may be positioned at a left side of the storage capping pattern 240, and the second channel pattern CP2 may be positioned at a right side of the storage capping pattern 240. The first channel pattern CP1 and the second channel pattern CP2 may contact the side surface of the storage capping pattern 240. However, the present disclosure is not limited thereto, and another layer may be further positioned between at least one of the first channel pattern CP1 or the second channel pattern CP2 and the storage capping pattern 240.

The first channel pattern CP1 and the second channel pattern CP2 may be connected to the first storage contact SC1 and the second storage contact SC2, respectively. The first channel pattern CP1 may be electrically connected to the first storage contact SC1. The first channel pattern CP1 may be in contact with the upper surface of the first storage contact SC1. The second channel pattern CP2 may be electrically connected to the second storage contact SC2. The second channel pattern CP2 may be in contact with the upper surface of the second storage contact SC2. Numbers of first channel pattern CP1 and second channel pattern CP2 may correspond to numbers of first storage contacts SC1 and second storage contacts SC2, respectively. The number of first channel patterns CP1 may be substantially equal to the number of first storage contacts SC1. The number of second channel patterns CP2 may be substantially equal to the number of second storage contacts SC2.

The first channel pattern CP1 and the second channel pattern CP2 may respectively include first vertical portions CP1a and CP2a extending along the third direction DR3, and horizontal portions CP1b and CP2b extending from the first vertical portions CP1a and CP2a.

The first vertical portion CP1a of the first channel pattern CP1 may be positioned at one side, e.g., the left side, of the gate insulating pattern GI and the storage capping pattern 240. The width of the first channel pattern CP1 in the first direction DR1 may be smaller than the length of the first word line WL1 in the third direction DR3. A length of the first channel pattern CP1 along the third direction DR3 may be similar to a sum of a length of the gate insulating pattern GI along the third direction DR3 and a length of the storage capping pattern 240 along the third direction DR3. The horizontal portion CP1b of the first channel pattern CP1 may extend in a horizontal direction on the upper surface of the substrate 100. The horizontal portion CP1b of the first channel pattern CP1 may extend in the first direction DR1. The horizontal portion CP1b of the first channel pattern CP1 may be positioned on the first storage contact SC1 and the second interlayer insulating layer 230. The horizontal portion CP1b of the first channel pattern CP1 may be in contact with the first storage contact SC1, and may be electrically connected to the first storage contact SC1. The first channel pattern CP1 includes the horizontal portion CP1b, so a contact area with the first storage contact SC1 may be further expanded. Accordingly, contact resistance between the first channel pattern CP1 and the first storage contact SC1 may be reduced, thereby improving an electric characteristic of the semiconductor device according to embodiments.

The first vertical portion CP2a of the second channel pattern CP2 may be positioned at the other side, e.g., the right side, of the gate insulating pattern GI and the storage capping pattern 240. The width of the second channel pattern CP2 in the first direction DR1 may be smaller than the length of the first word line WL1 in the third direction DR3. A length of the second channel pattern CP2 along the third direction DR3 may be similar to a sum of a length of the gate insulating pattern GI along the third direction DR3 and a length of the storage capping pattern 240 along the third direction DR3. The horizontal portion CP2b of the second channel pattern CP2 may extend in a horizontal direction on the upper surface of the substrate 100. The horizontal portion CP2b of the second channel pattern CP2 may extend in the first direction DR1. The horizontal portion CP2b of the second channel pattern CP2 may be positioned on the second storage contact SC2 and the second interlayer insulating layer 230. The horizontal portion CP2b of the second channel pattern CP2 may be in contact with the second storage contact SC2, and may be electrically connected to the second storage contact SC2. The second channel pattern CP2 includes the horizontal portion CP2b, so a contact area with the second storage contact SC2 may be further expanded. Accordingly, contact resistance between the second channel pattern CP2 and the second storage contact SC2 may be reduced, thereby improving an electric characteristic of the semiconductor device according to embodiments.

The first channel pattern CP1 and the second channel pattern CP2 may include a semiconductor material. The first channel pattern CP1 and the second channel pattern CP2 may include an oxide semiconductor material. The oxide semiconductor material may be a combination of at least two of In, Ga, Zn, Al, Sn, and Hf, but the present disclosure is not limited thereto. The oxide semiconductor material may further include a material such as Si, Mg, Ta, La, Nd, Ce, Sc, Cr, Co, Nb, Mo, Ba, Gd, Ti, W, Pd, Ru, Ni, or Mn in the composition. For example, the first channel pattern CP1 and the second channel pattern CP2 may include an indium gallium zinc oxide (IGZO), an indium tin zinc oxide (ITZO), an indium zinc oxide (IZO), a zinc oxide (ZnO), a zinc tin oxide (ZTO), a zinc oxynitride (ZnON), a zirconium zinc tin oxide (ZZTO), a tin oxide (SnO), a hafnium indium zinc oxide (HIZO), a gallium zinc tin oxide (GZTO), an aluminum zinc tin oxide (AZTO), a ytterbium gallium zinc oxide (YGZO), an indium gallium oxide (IGO) or a combination thereof. However, the present disclosure is not limited thereto, and the oxide semiconductor material included in the first channel pattern CP1 and the second channel pattern CP2 may be changed in various ways.

The semiconductor device according to some embodiments may further include a second insulating pattern MD2 positioned between the first insulating patterns MD1. For example, the second insulating pattern MD2 may be adjacent to the first insulating pattern MD1 along the first direction DR1. According to some embodiments, the semiconductor device may include a plurality of second insulating patterns MD2. The second insulating patterns MD2 may be positioned to be spaced apart from each other along the first direction DR1. As used herein, a pair of second insulating patterns MD2 on opposite sides of a respective first insulating pattern MD1 may be considered as one second insulating pattern MD2 rather than separate patterns. The second insulating pattern MD2 may include a gap-fill insulating layer MD2a, a capping insulating layer MD2b surrounding the gap-fill insulating layer MD2a, and an insulating liner MD2c positioned at opposite sides of the capping insulating layer MD2b.

The gap-fill insulating layer MD2a may be positioned to be in (e.g., to fill) a space between adjacent first insulating patterns MD1. The gap-fill insulating layer MD2a may be positioned approximately at a center of the second insulating pattern MD2. The gap fill insulating layer MD2a may be located approximately at the center of the space between adjacent first insulating patterns MD1.

The capping insulating layer MD2b may surround the side and lower surfaces of the gap-fill insulating layer MD2a. An upper surface of the gap-fill insulating layer MD2a may not be covered by the capping insulating layer MD2b. The upper surface of the capping insulating layer MD2b may be positioned at substantially a same level as the upper surface of the gap-fill insulating layer MD2a. For example, the upper surface of the capping insulating layer MD2b may be coplanar with the upper surface of the gap-fill insulating layer MD2a. The upper surface of the capping insulating layer MD2b, the upper surface of the gap-fill insulating layer MD2a, the upper surface of the first channel pattern CP1, the upper surface of the gate insulating pattern GI, and the upper surface of the second channel pattern CP2 may be positioned at substantially a same level. For example, the upper surface of the capping insulating layer MD2b, the upper surface of the gap-fill insulating layer MD2a, the upper surface of the first channel pattern CP1, the upper surface of the gate insulating pattern GI, and the upper surface of the second channel pattern CP2 may be coplanar with each other. The capping insulating layer MD2b may be positioned between the gap-fill insulating layer MD2a and the insulating liner MD2c. The capping insulating layer MD2b may be positioned between the gap-fill insulating layer MD2a and the second interlayer insulating layer 230.

The insulating liner MD2c may be separated from each other at opposite sides of the capping insulating layer MD2b. The insulating liner MD2c may be positioned between the first channel pattern CP1 and the capping insulating layer MD2b, and may be positioned between the second channel pattern CP2 and the capping insulating layer MD2b. An upper surface of the insulating liner MD2c may be positioned at a different level from upper surfaces of the first and second channel patterns CP1 and CP2. The upper surface of the insulating liner MD2c may be positioned at a lower level than the upper surface of the first channel pattern CP1. The upper surface of the insulating liner MD2c may be positioned at a lower level than the upper surface of the second channel pattern CP2. For example, the upper surface of the insulating liner MD2c may be lower than the upper surfaces of the first and second channel patterns CP1 and CP2, with the upper surface of the substrate 100 providing a base reference plane. The upper surface of the insulating liner MD2c may be positioned at a different level from the upper surfaces of the gap-fill insulating layer MD2a and the capping insulating layer MD2b. The upper surface of the insulating liner MD2c may be positioned at a lower level than the upper surface of the gap-fill insulating layer MD2a. The upper surface of the insulating liner MD2c may be positioned at a lower level than the upper surface of the capping insulating layer MD2b. For example, the upper surface of the insulating liner MD2c may be lower than the upper surfaces of the gap-fill insulating layer MD2a and the capping insulating layer MD2b, with the upper surface of the substrate 100 providing a base reference plane.

The first word line WL1 and the first channel pattern CP1 may be positioned between the first insulating pattern MD1 and the second insulating pattern MD2. The first channel pattern CP1 may be positioned between the gate insulating pattern GI and the second insulating pattern MD2. The first vertical portion CP1a of the first channel pattern CP1 may be positioned between the gate insulating pattern GI and the second insulating pattern MD2. Side and lower surfaces of the second insulating pattern MD2 may be covered by the first channel pattern CP1. A side surface of the second insulating pattern MD2 may be covered by the first vertical portion CP1a of the first channel pattern CP1, and a lower surface of the second insulating pattern MD2 may be covered by the horizontal portion CP1b of the first channel pattern CP1. The first vertical portion CP1a of the first channel pattern CP1 may be on (e.g., may cover) the side surface of the insulating liner MD2c. The horizontal portion CP1b of the first channel pattern CP1 may be on (e.g., may cover) a lower surface of the insulating liner MD2c.

The second word line WL2 and the second channel pattern CP2 may be positioned between the first insulating pattern MD1 and the second insulating pattern MD2. The second channel pattern CP2 may be positioned between the gate insulating pattern GI and the second insulating pattern MD2. The first vertical portion CP2a of the second channel pattern CP2 may be positioned between the gate insulating pattern GI and the second insulating pattern MD2. Side and lower surfaces of the second insulating pattern MD2 may be covered by the second channel pattern CP2. A side surface of the second insulating pattern MD2 may be covered by the first vertical portion CP2a of the second channel pattern CP2, and a lower surface of the second insulating pattern MD2 may be covered by the horizontal portion CP2b of the second channel pattern CP2. The first vertical portion CP2a of the second channel pattern CP2 may be on (e.g., may cover) the side surface of the insulating liner MD2c. The horizontal portion CP2b of the second channel pattern CP2 may be on (e.g., may cover) a lower surface of the insulating liner MD2c.

The second insulating pattern MD2 may include an insulating material. For example, the second insulating pattern MD2 include a silicon oxide, a silicon nitride, a silicon oxynitride, a high-k material having a higher dielectric constant than silicon oxide, or a combination thereof. At least one of the gap-fill insulating layer MD2a, the capping insulating layer MD2b, or the insulating liner MD2c constituting the second insulating pattern MD2 may include a different material. For example, the gap fill insulating layer MD2a and the insulating liner MD2c may include silicon oxide, and the capping insulating layer MD2b may include a high dielectric constant material such as Al₂O₃. However, this is merely an example, and materials of the gap-fill insulating layer MD2a, the capping insulating layer MD2b, and the insulating liner MD2c may vary.

The bit line BL may be positioned on the first channel pattern CP1 and the second channel pattern CP2. The bit line BL may be in contact with the first channel pattern CP1 and the second channel pattern CP2. The bit line BL may extend along the first direction DR1. A plurality of bit lines BL may be positioned to be spaced apart along the second direction DR2. Each of the bit lines BL may be connected to a plurality of first channel patterns CP1 and a plurality of second channel patterns CP2. The first channel pattern CP1 and the second channel pattern CP2 may be alternately and repeatedly positioned along the first direction DR1. The bit lines BL may be connected to a plurality of first channel patterns CP1 and a plurality of second channel patterns CP2 spaced apart from each other along the first direction DR1.

The bit lines BL may be on (e.g., may cover) upper and side surfaces of the first channel pattern CP1. The bit lines BL may protrude into a space between the first channel pattern CP1 and the capping insulating layer MD2b. A protrusion of the bit line BL may be on (e.g., may cover) a portion of the side surface of the first channel pattern CP1. As the bit line BL contacts not only the upper surface but also a portion of the side surface of the first channel pattern CP1, a contact area with the first channel pattern CP1 may be expanded. Accordingly, contact resistance between the first channel pattern CP1 and the bit line BL may be reduced, thereby improving an electric characteristic of the semiconductor device according to embodiments. The bit lines BL may be on (e.g., may cover) upper and side surfaces of the second channel pattern CP2. The bit lines BL may protrude into a space between the second channel pattern CP2 and the capping insulating layer MD2b. A protrusion of the bit line BL may be on (e.g., may cover) a portion of the side surface of the second channel pattern CP2. As the bit line BL contacts not only the upper surface but also a portion of the side surface of the second channel pattern CP2, a contact area with the second channel pattern CP2 may be expanded. Accordingly, contact resistance between the second channel pattern CP2 and the bit line BL may be reduced, thereby improving an electric characteristic of the semiconductor device according to embodiments.

A width of the bit line BL in the second direction DR2 may be smaller than a width of the first channel pattern CP1 in the second direction DR2. The width of the bit line BL in the second direction DR2 may be smaller than a width of the second channel pattern CP2 in the second direction DR2. A distance between adjacent bit lines BL may be sufficiently secured, minimizing interference between the bit lines BL.

The bit line BL may be positioned on the gate insulating pattern GI. The bit line BL may be spaced apart from the first word line WL1 with the gate insulating pattern GI therebetween. The gate insulating pattern GI may be positioned between the bit line BL and the first word line WL1. The gate insulating pattern GI may be positioned between the bit line BL and the second word line WL2. The bit line BL may be spaced apart from the second word line WL2 with the gate insulating pattern GI provided therebetween. The bit line BL may be spaced apart from the first insulating pattern MD1 with the gate insulating pattern GI therebetween.

The bit line BL may include a doped polysilicon, a metal, a conductive metal nitride, a conductive metal silicide, a conductive metal oxide, or a combination thereof. For example, the bit lines BL may be formed to include Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOx, RuOx, or a combination thereof, but the present disclosure is not limited thereto.

The semiconductor device according to some embodiments may further include a bit line capping layer 260 positioned on the bit line BL and a shield pattern BLS positioned on the bit line capping layer 260.

The bit line capping layer 260 may be on (e.g., may cover) upper and side surfaces of the bit line BL. The bit line capping layer 260 may be positioned on the gap fill insulating layer MD2a, the capping insulating layer MD2b, the first channel pattern CP1, and the second channel pattern CP2. The bit line capping layer 260 may be on (e.g., may cover) the upper surfaces of the gap-fill insulating layer MD2a, the capping insulating layer MD2b, the first channel pattern CP1, and the second channel pattern CP2 between the bit lines BL. The bit line capping layer 260 may include a lower layer 262 and an upper layer 264. The upper layer 264 may be disposed on the lower layer 262.

The bit line capping layer 260 may include an insulating material. For example, the bit line capping layer 260 may include a silicon oxide, a silicon nitride, a silicon oxynitride, or a combination thereof. The lower layer 262 and the upper layer 264 constituting the bit line capping layer 260 may include different materials. For example, the lower layer 262 may include silicon nitride, and the upper layer 264 may include silicon oxide.

The shield pattern BLS may be entirely positioned on the bit line capping layer 260. The shield pattern BLS may be spaced apart from the bit line BL by the bit line capping layer 260. The shield pattern BLS may overlap the bit line BL in the third direction DR3. The shield pattern BLS may also overlap a space between the bit lines BL in the third direction DR3. The shield pattern BLS may be positioned between the bit lines BL. The shield pattern BLS may overlap the bit line BL in the second direction DR2. The shield pattern BLS may reduce disturbance and parasitic capacitance between the bit lines BL. Accordingly, a delay (RC-delay) of a signal applied to the bit line BL may be reduced, and an operating speed of the semiconductor device according to embodiments may be improved.

The shield pattern BLS may include a doped polysilicon, a metal, a conductive metal nitride, a conductive metal oxide, or a combination thereof. For example, the shield pattern BLS may be formed to include Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOx, RuOx, or a combination thereof, but the present disclosure is not limited thereto.

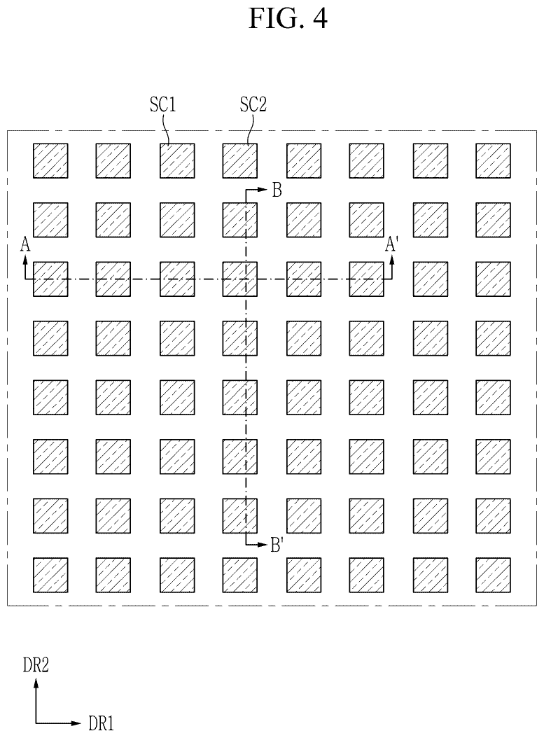

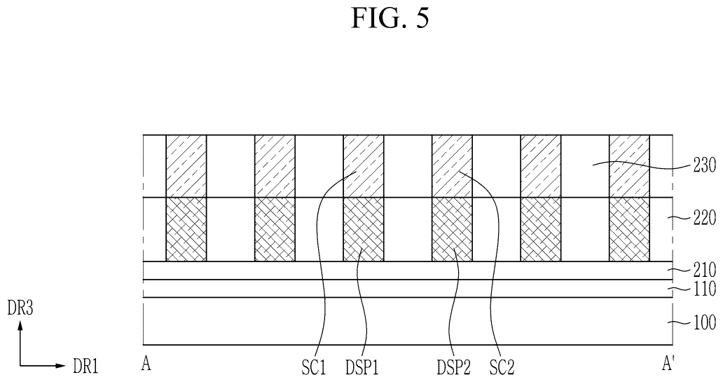

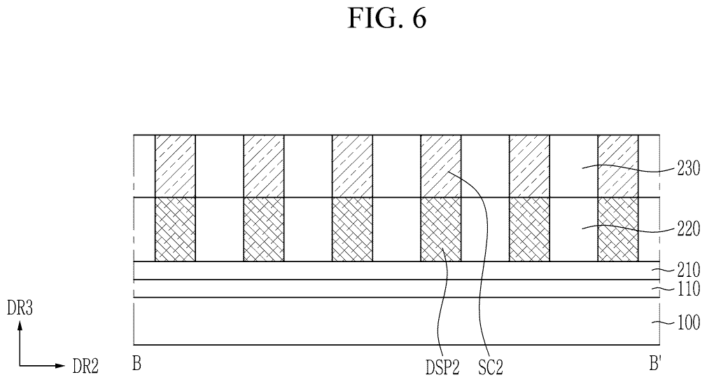

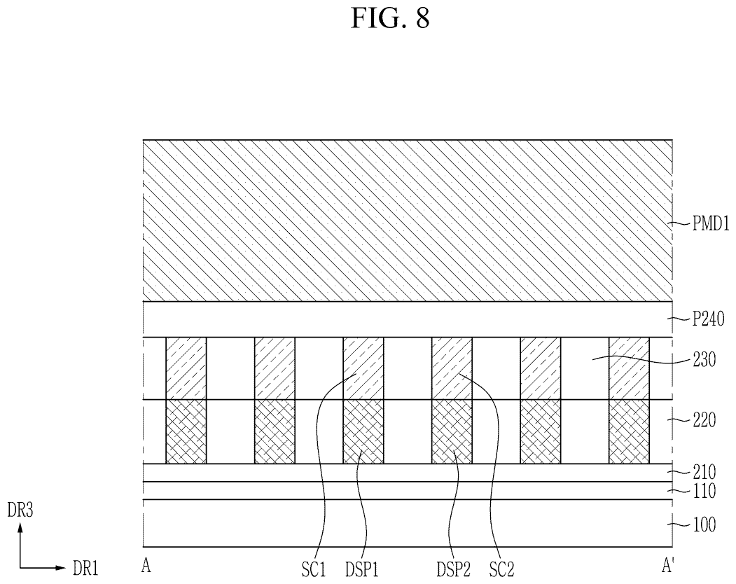

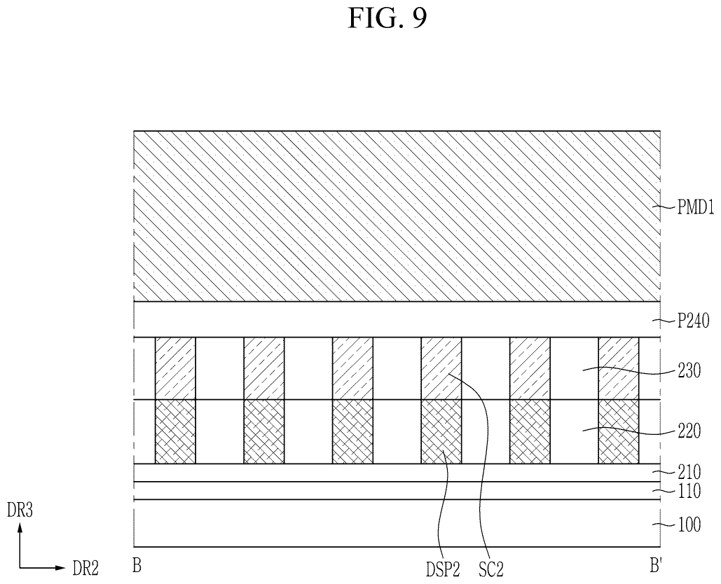

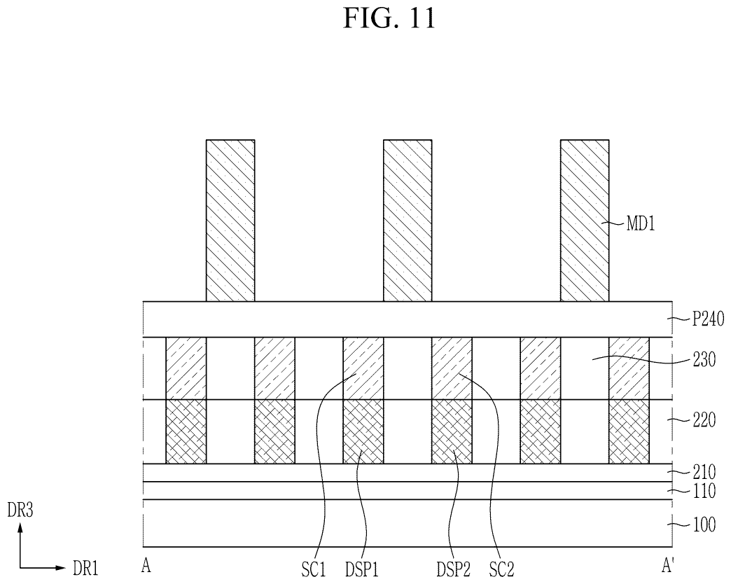

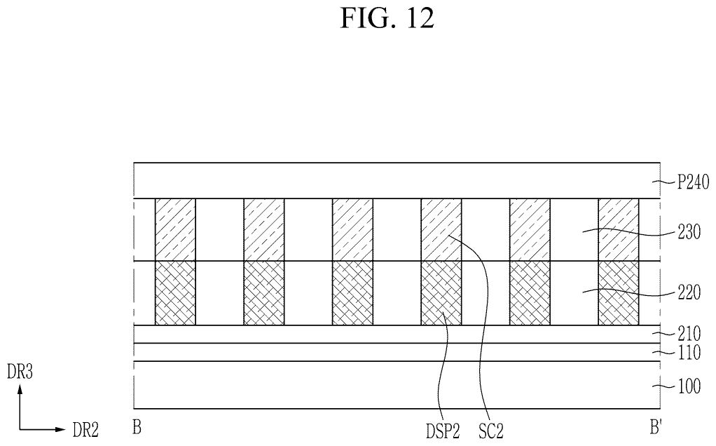

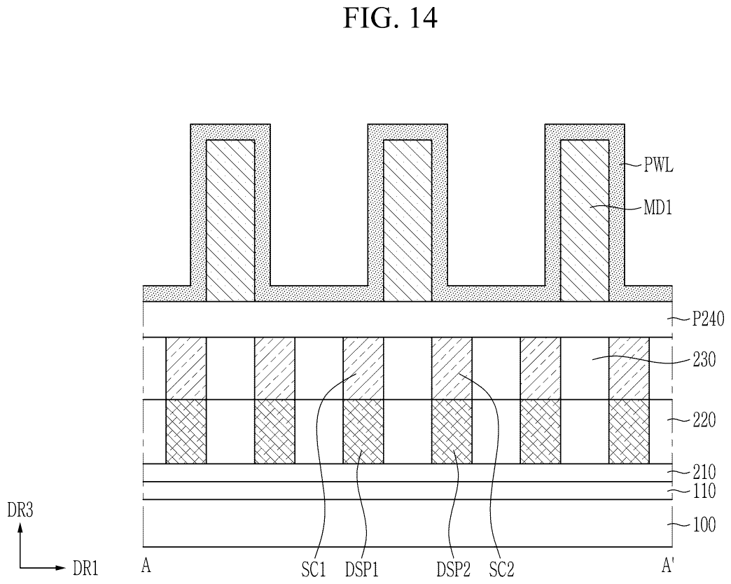

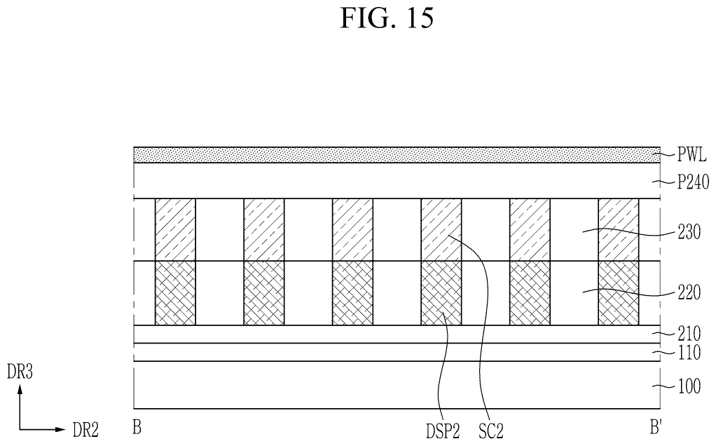

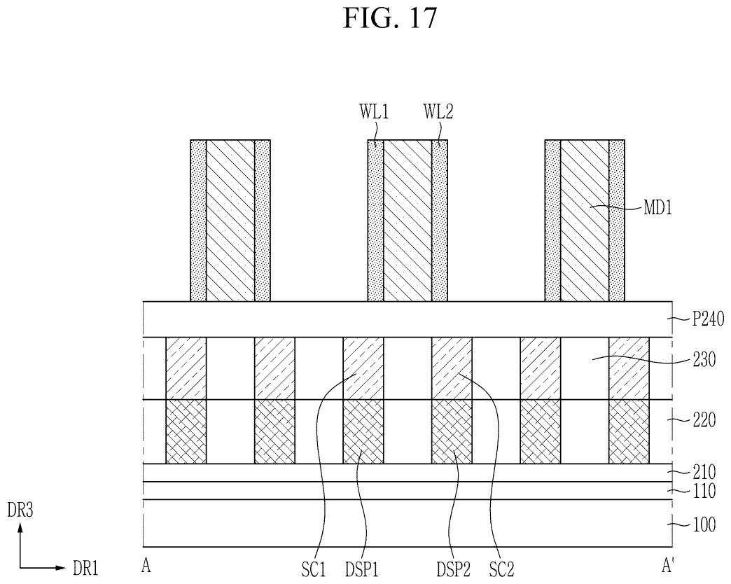

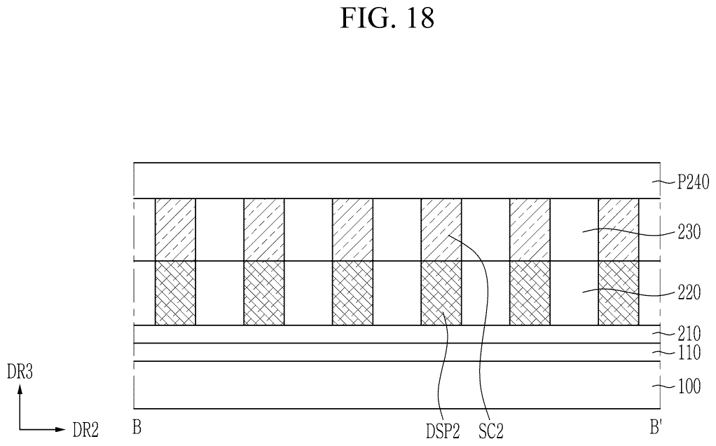

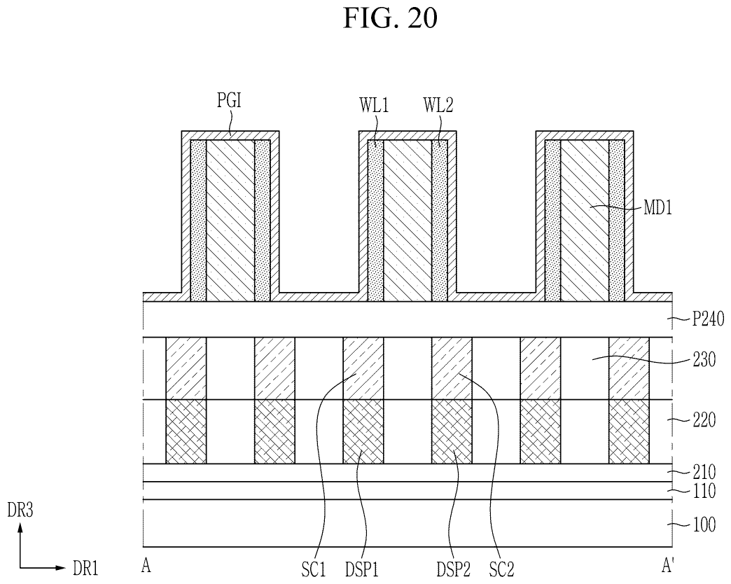

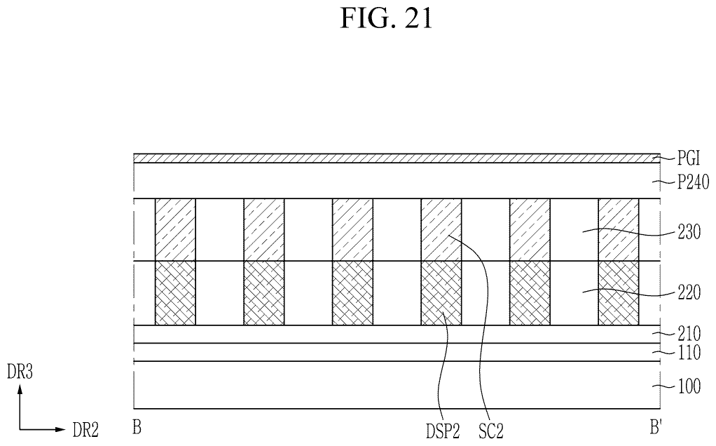

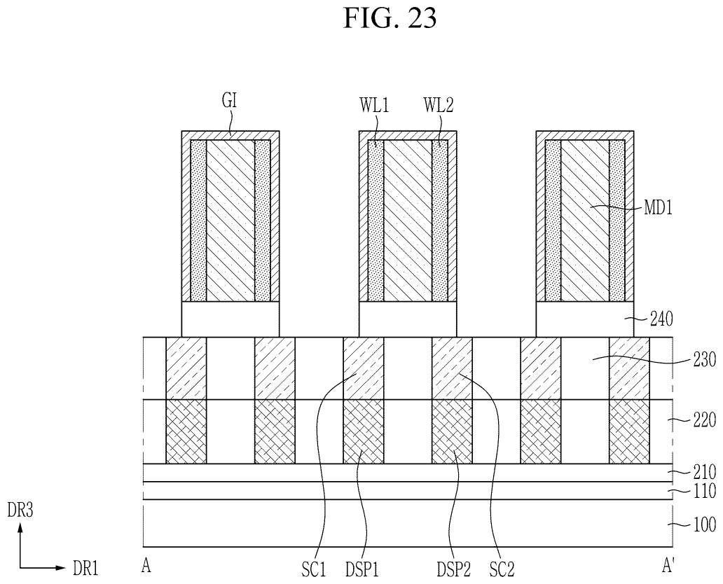

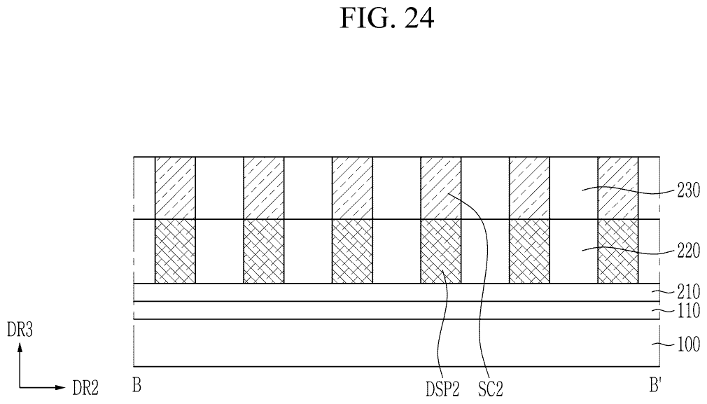

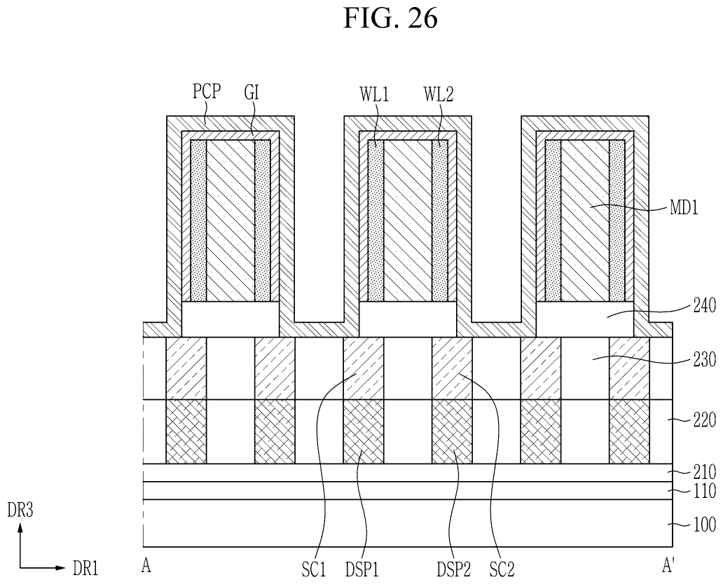

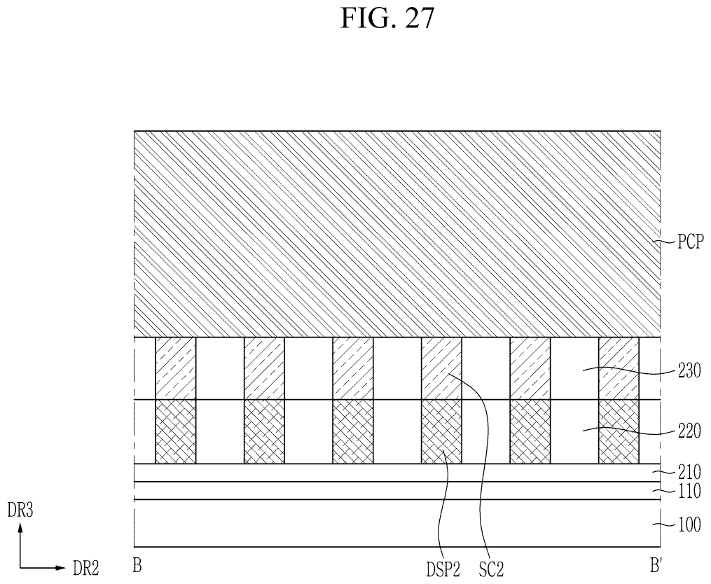

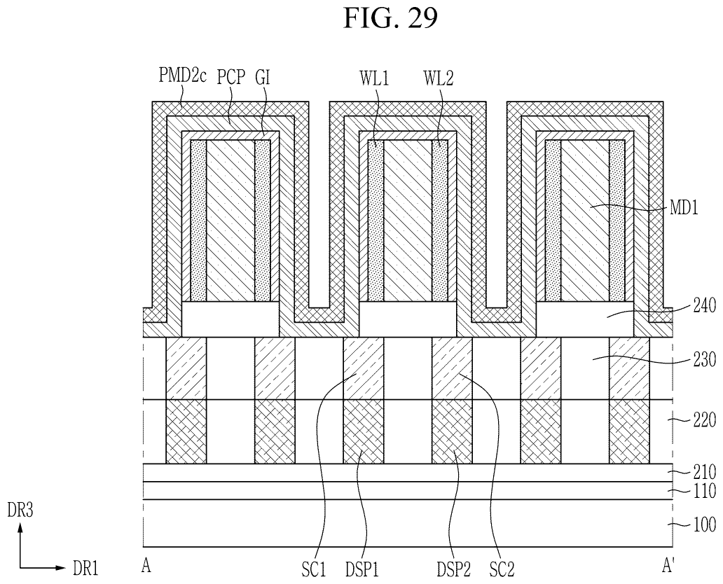

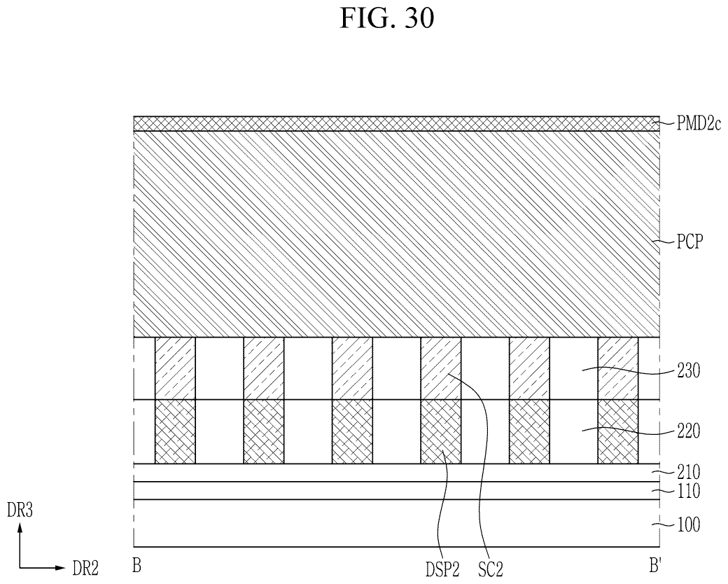

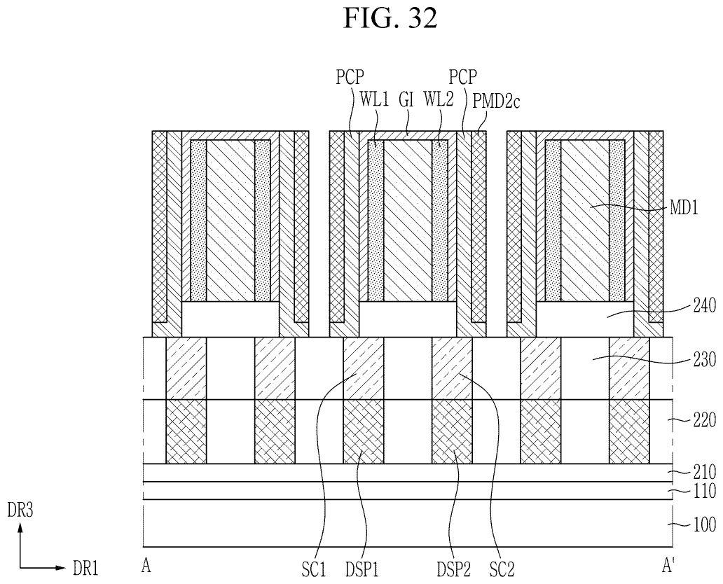

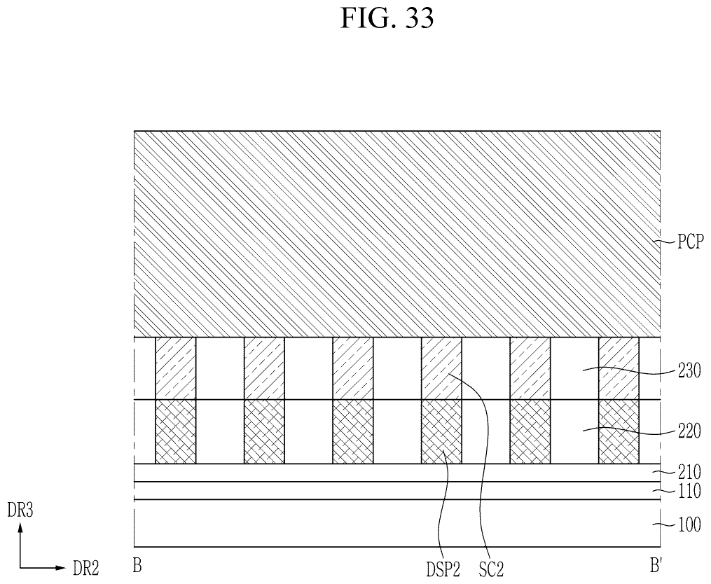

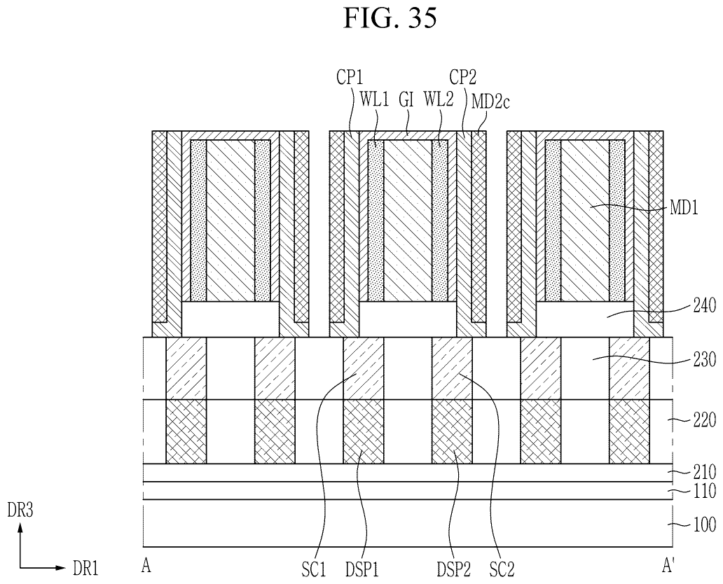

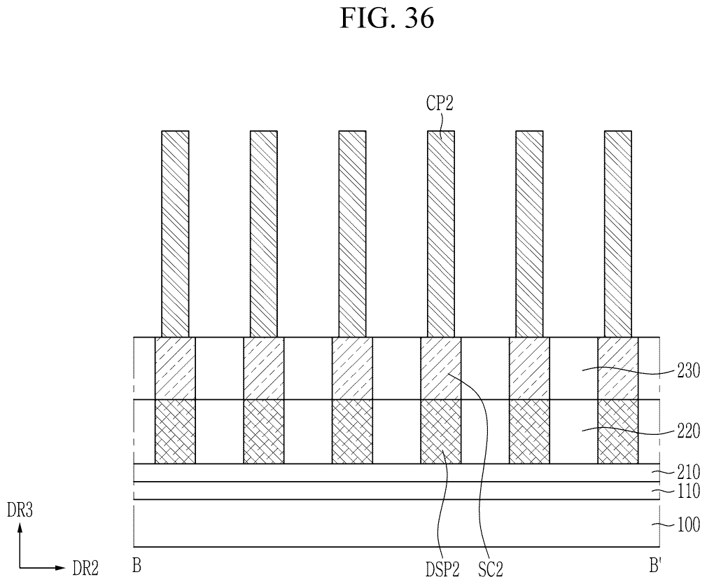

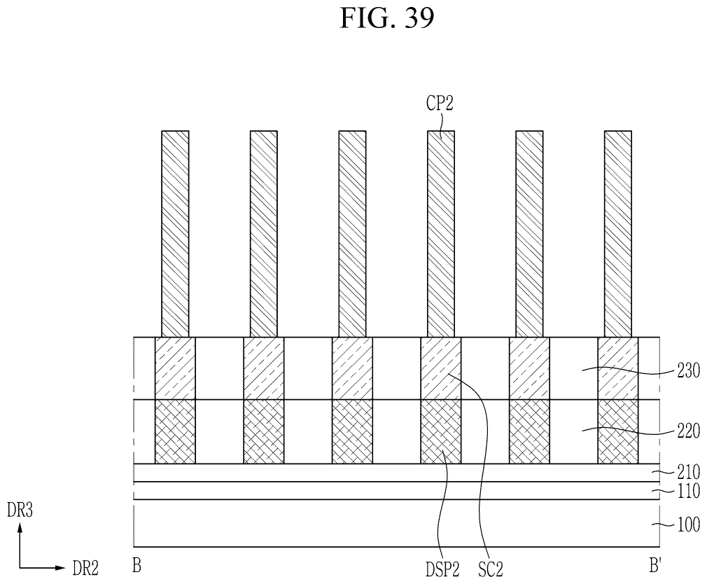

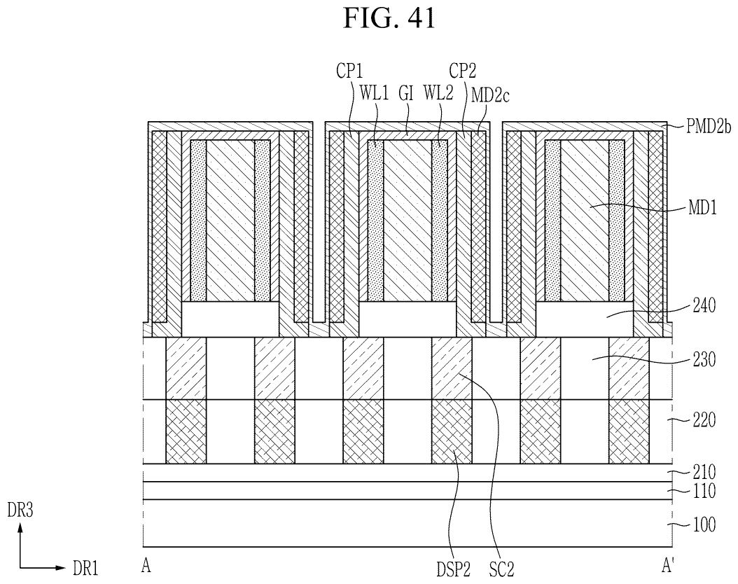

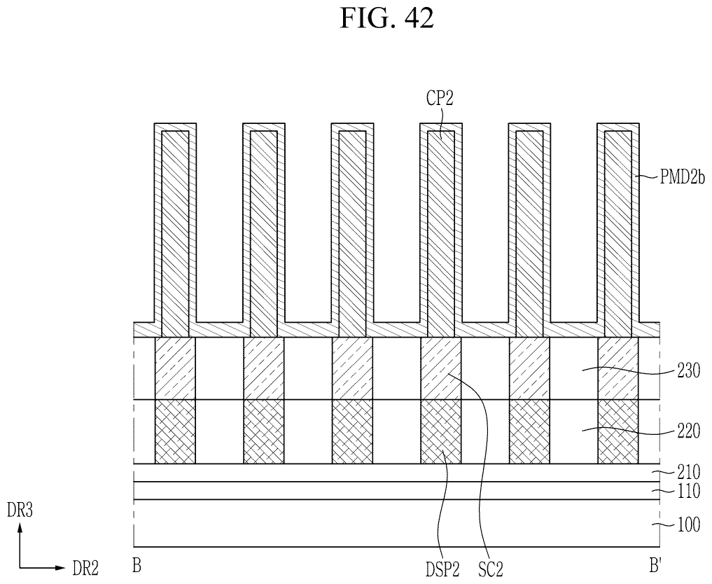

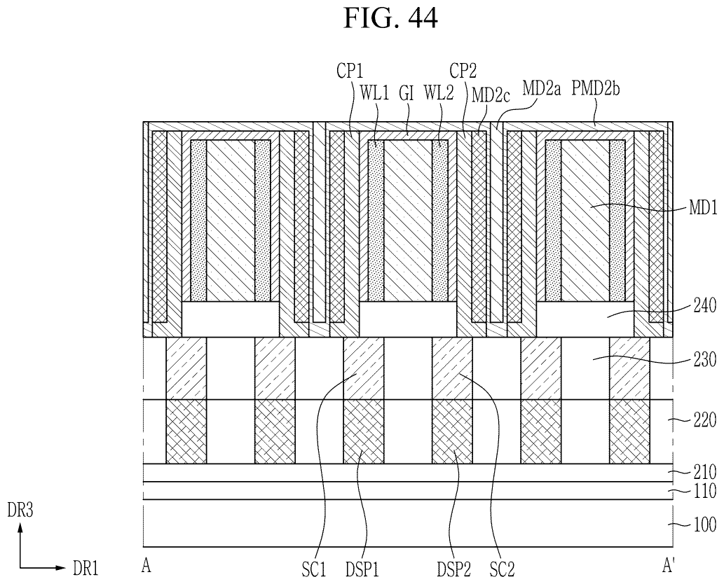

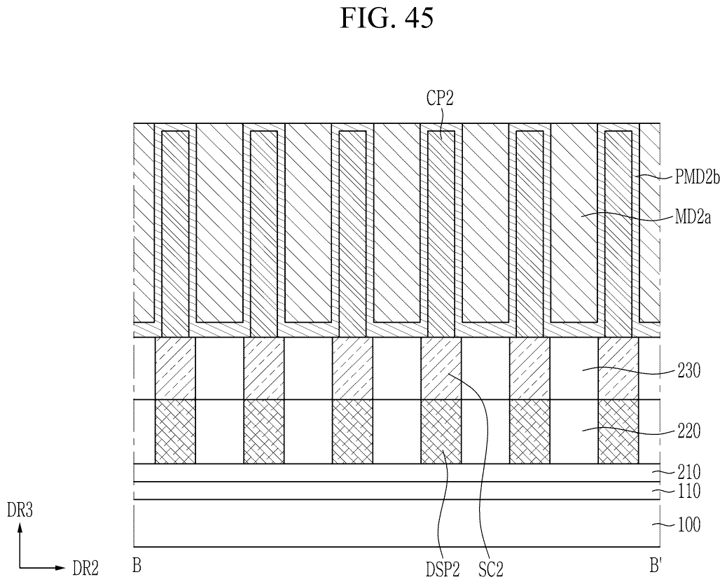

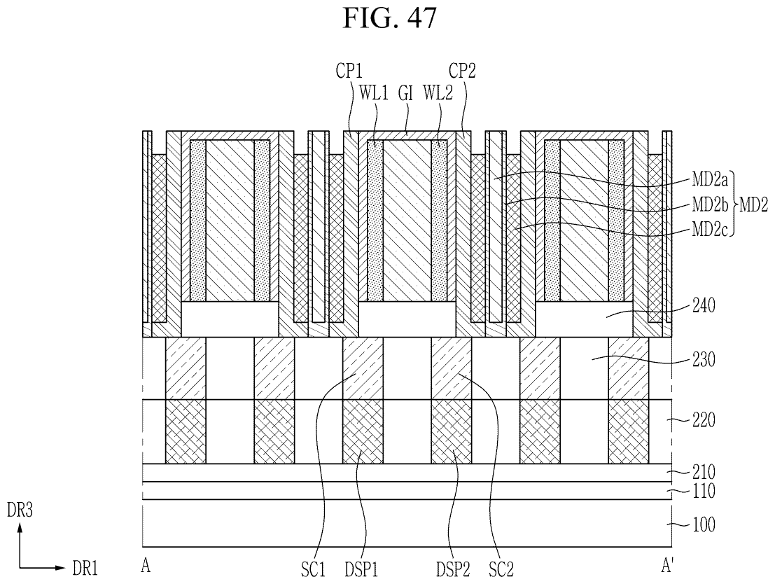

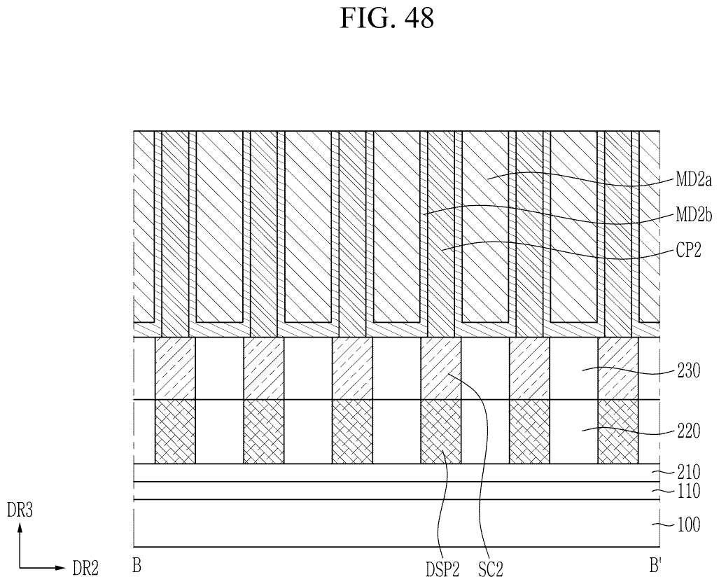

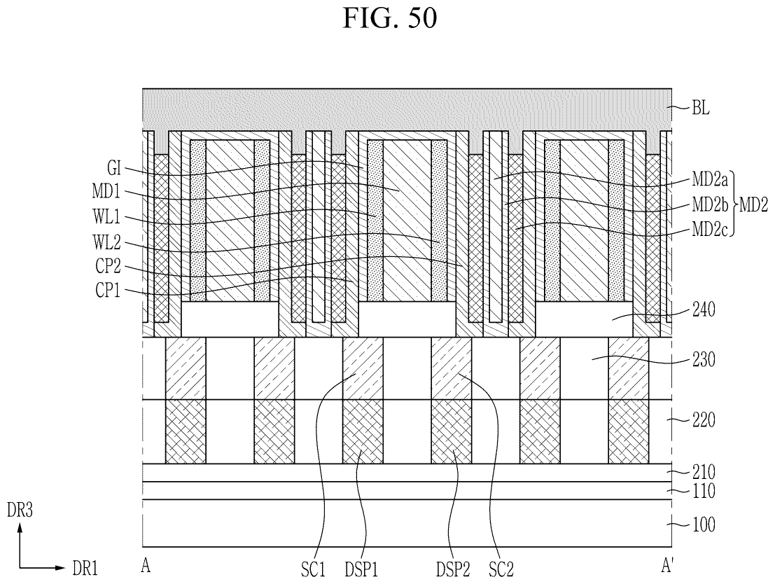

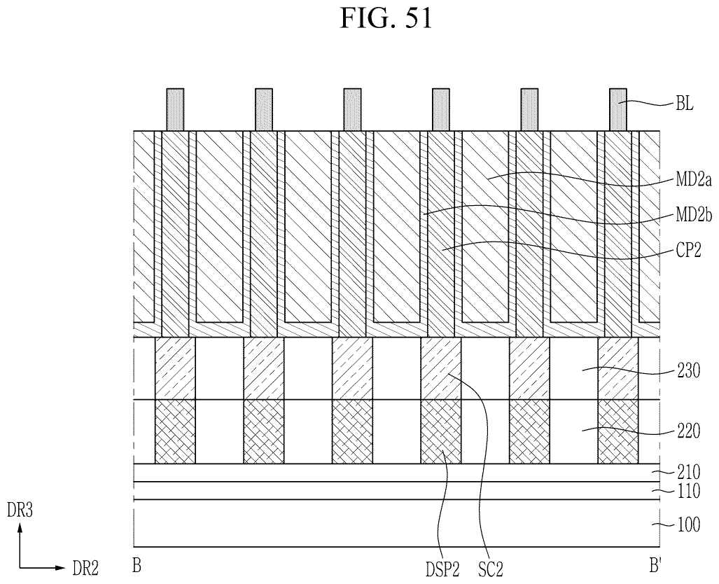

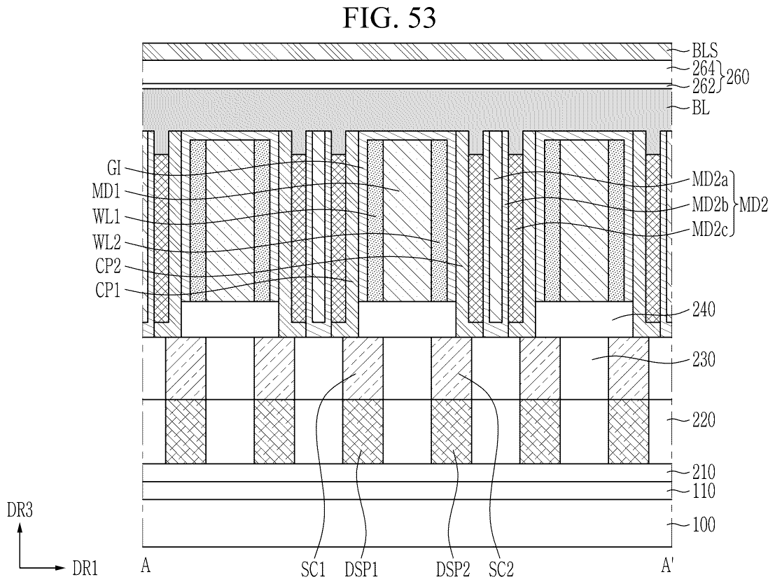

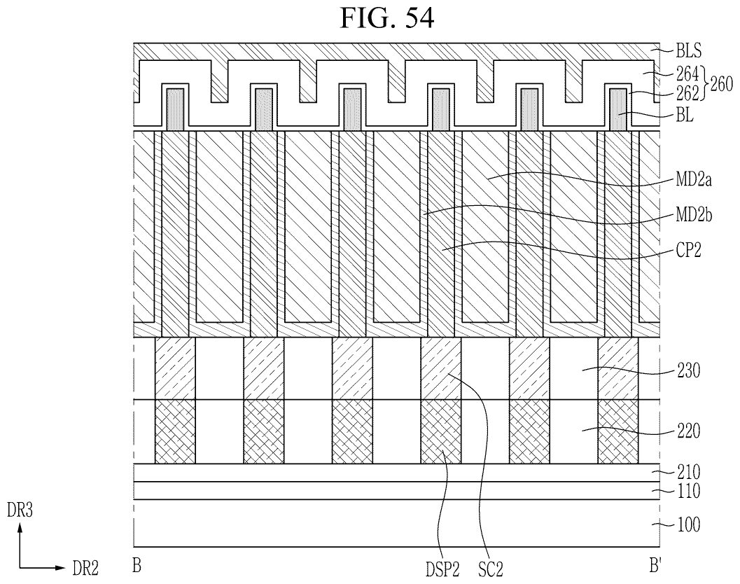

Hereinafter, a manufacturing method of a semiconductor device according to some embodiments will be described with reference to FIGS. 4 to 54.

FIGS. 4 to 54 each illustrate a process plan view or process cross-sectional view sequentially illustrating a manufacturing method of a semiconductor device according to some embodiments.

First, as shown in FIGS. 4 to 6, the first bonding insulating layer 110 may be disposed on the substrate 100 using an insulating material. Prior to forming the first bonding insulating layer 110, driving circuits such as a sense amplifier, a subword line driver, a row decoder, and a column decoder, and wires connected thereto may be formed on the substrate 100. The first bonding insulating layer 110 may be positioned on the driving circuits and the wires.

Although not shown, the first storage contact SC1 and the second storage contact SC2 may be positioned on an opposing substrate, the first data storage pattern DSP1 and the second data storage pattern DSP2 may be positioned on the first storage contact SC1 and the second storage contact SC2, and the second bonding insulating layer 210 may be disposed on the first data storage pattern DSP1 and the second data storage pattern DSP2.

A conductive material such as a doped polysilicon, a metal, a conductive metal nitride, or a conductive metal oxide may be deposited on the opposing substrate and patterned to form the first storage contact SC1 and the second storage contact SC2. The first storage contact SC1 and the second storage contact SC2 may be spaced apart from each other along the first direction DR1. The first storage contact SC1 and the second storage contact SC2 may be alternately positioned along the first direction DR1. The first storage contacts SC1 may be spaced apart from each other along the second direction DR2, and the second storage contacts SC2 may be spaced apart from each other along the second direction DR2. That is, a row formed of the first storage contacts SC1 and a row formed of the second storage contacts SC2 may be alternately and repeatedly positioned.

The second interlayer insulating layer 230 may be further formed between the first storage contact SC1 and the second storage contact SC2. The second interlayer insulating layer 230 may be formed by depositing an insulating material such as a silicon oxide, a silicon nitride, a silicon oxynitride, etc. on the first storage contact SC1 and the second storage contact SC2. When a planarization process is performed, the insulating material positioned on upper surfaces of the first storage contact SC1 and the second storage contact SC2 may be removed, and an insulating material positioned between the first storage contact SC1 and the second storage contact SC2 may remain. Accordingly, an upper surface of the second interlayer insulating layer 230 may be positioned at the same level as (e.g., may be coplanar with) upper surfaces of the first and second storage contacts SC1 and SC2.

A conductive material may be deposited on the first storage contact SC1, the second storage contact SC2, and the second interlayer insulating layer 230, and patterned to form the first data storage pattern DSP1 and the second data storage pattern DSP2. Next, although not shown, the first data storage pattern DSP1 and the second data storage pattern DSP2 may become capacitors by depositing an insulating material and a conductive material.

The first data storage pattern DSP1 and the second data storage pattern DSP2 may be positioned on the first storage contact SC1 and the second storage contact SC2, respectively. The first data storage pattern DSP1 may be electrically connected to the first storage contact SC1, and the second data storage pattern DSP2 may be electrically connected to the second storage contact SC2. The first data storage pattern DSP1 and the second data storage pattern DSP2 may have substantially a same disposition as the first storage contact SC1 and the second storage contact SC2, respectively. The first data storage pattern DSP1 and the second data storage pattern DSP2 may be spaced apart from each other along the first direction DR1. The first data storage pattern DSP1 and the second data storage pattern DSP2 may be alternately formed along the first direction DR1. The first data storage patterns DSP1 may be spaced apart from each other along the second direction DR2, and the second data storage patterns DSP2 may be spaced apart from each other along the second direction DR2. That is, a row formed of the first data storage patterns DSP1 and a row formed of the second data storage patterns DSP2 may be alternately and repeatedly positioned.

The first interlayer insulating layer 220 may be further formed between the first data storage pattern DSP1 and the second data storage pattern DSP2. The first interlayer insulating layer 220 may be formed by depositing an insulating material on the first data storage pattern DSP1 and the second data storage pattern DSP2. When a planarization process is performed, the insulating material positioned on upper surfaces of the first data storage pattern DSP1 and the second data storage pattern DSP2 may be removed, and an insulating material positioned between the first data storage pattern DSP1 and the second data storage pattern DSP2 may remain. Accordingly, an upper surface of the first interlayer insulating layer 220 may be positioned at the same level as (e.g., may be coplanar with) upper surfaces of the first and second data storage patterns DSP1 and DSP2.

The second bonding insulating layer 210 may be disposed on the first data storage pattern DSP1, the second data storage pattern DSP2, and the first interlayer insulating layer 220 using an insulating material.

An opposing substrate is aligned on the substrate 100 to face the substrate 100. An upper surface of the opposing substrate faces an upper surface of the substrate 100, and the first bonding insulating layer 110 and the second bonding insulating layer 210 are adjacent to each other. The substrate 100 and the opposing substrate are bonded. The first bonding insulating layer 110 and the second bonding insulating layer 210 may be bonded using a dielectric bonding method.

The first bonding insulating layer 110, the second bonding insulating layer 210, the first data storage pattern DSP1 and the second data storage pattern DSP2, the first storage contact SC1, and the second storage contact SC2 are sequentially positioned on the substrate 100. The opposing substrate positioned on first storage contact SC1 and the second storage contact SC2 may be removed through a grinding process, an etching process, etc.

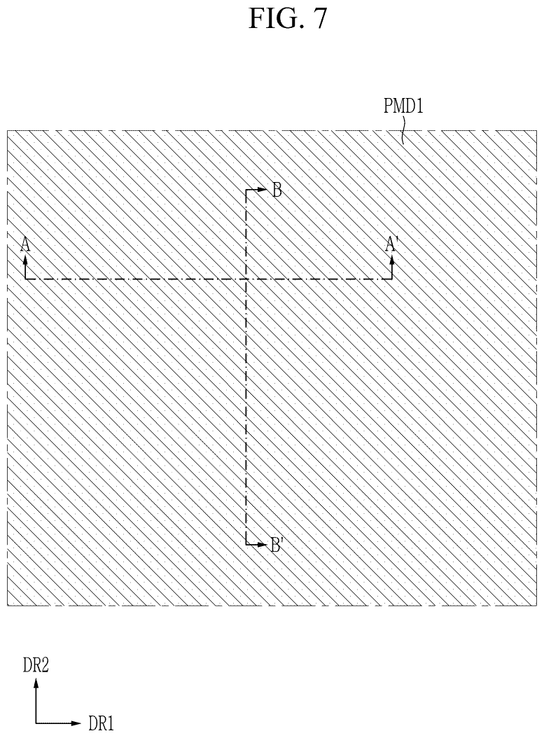

As illustrated in FIGS. 7 to 9, a storage capping material layer P240 and a first insulating material layer PMD1 may be formed by sequentially depositing an insulating material on the first storage contact SC1, the second storage contact SC2, and the second interlayer insulating layer 230. The storage capping material layer P240 may be positioned on the first storage contact SC1, the second storage contact SC2, and the second interlayer insulating layer 230, and the first insulating material layer PMD1 may be positioned on the storage capping material layer P240. The storage capping material layer P240 may be formed to entirely be on (e.g., to entirely cover) the first storage contact SC1, the second storage contact SC2, and the second interlayer insulating layer 230. The first insulating material layer PMD1 may be formed to entirely be on (e.g., to entirely cover) the storage capping material layer P240.

The storage capping material layer P240 and the first insulating material layer PMD1 may include different insulating materials. The storage capping material layer P240 and the first insulating material layer PMD1 may have different etch rates. For example, the storage capping material layer P240 may include a silicon nitride, and the first insulating material layer PMD1 may include a low dielectric constant material. However, the present disclosure is not limited thereto, and materials of the storage capping material layer P240 and the first insulating material layer PMD1 may be changed in various ways.

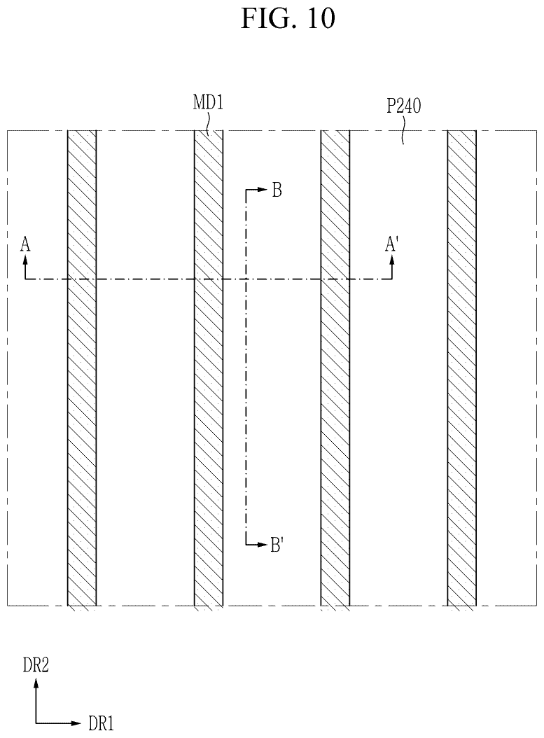

As shown in FIGS. 10 to 12, the first insulating material layer PMD1 may be patterned to form the first insulating pattern MD1. The first insulating pattern MD1 may extend along the second direction DR2. The first insulating patterns MD1 may be spaced apart from each other along the first direction DR1. A length of the first insulating pattern MD1 along the third direction DR3 may be greater than a width of the first insulating pattern MD1 along the first direction DR1.

The first insulating pattern MD1 may overlap a region between the first storage contact SC1 and the second storage contact SC2 in the third direction DR3. The width of the first insulating pattern MD1 along the first direction DR1 may be similar to a distance between the first storage contact SC1 and the second storage contact SC2. The first insulating pattern MD1 may overlap the first storage contact SC1 and the second storage contact SC2 in the third direction DR3. A row formed of the first storage contacts SC1 and a row formed of the second storage contacts SC2 may constitute a pair of storage contact rows. The first insulating pattern MD1 may overlap between rows of the first storage contact SC1 and second storage contact SC2 constituting a pair of storage contact rows. The first insulating pattern MD1 may not be positioned between one pair of storage contact rows and another pair of storage contact rows.

The first insulating pattern MD1 may overlap a region between the first data storage pattern DSP1 and the second data storage pattern DSP2 in the third direction DR3. The width of the first insulating pattern MD1 along the first direction DR1 may be similar to a distance between the first data storage pattern DSP1 and the second data storage pattern DSP2. The first insulating pattern MD1 may overlap the first data storage pattern DSP1 and the second data storage pattern DSP2 in the third direction DR3. A row formed of a plurality of first data storage patterns DSP1 and a row formed of a plurality of second data storage patterns DSP2 may constitute a pair of data storage rows. The first insulating pattern MD1 may be positioned between rows of the first data storage pattern DSP1 and the second data storage pattern DSP2 constituting a pair of data storage rows. The first insulating pattern MD1 may not be positioned between one pair of data storage pattern rows and another pair of data storage pattern rows.

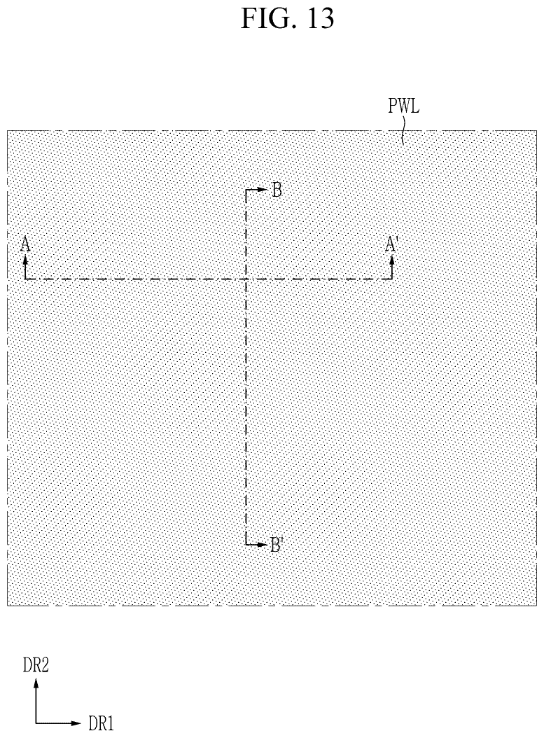

As shown in FIGS. 13 to 15, a word line material layer PWL may be formed by depositing a conductive material on the first insulating pattern MD1 and the storage capping material layer P240. The word line material layer PWL may be on (e.g., may cover) upper and side surfaces of the first insulating pattern MD1 and an upper surface of the storage capping material layer P240. The word line material layer PWL may be formed conformally. A thickness of a portion of the word line material layer PWL positioned on the upper surface of the first insulating pattern MD1 and the upper surface of the storage capping material layer P240 in the third direction DR3 may be similar to a thickness of a portion of the word line material layer PWL positioned on a side position of the first insulating pattern MD1 along the first direction DR1.

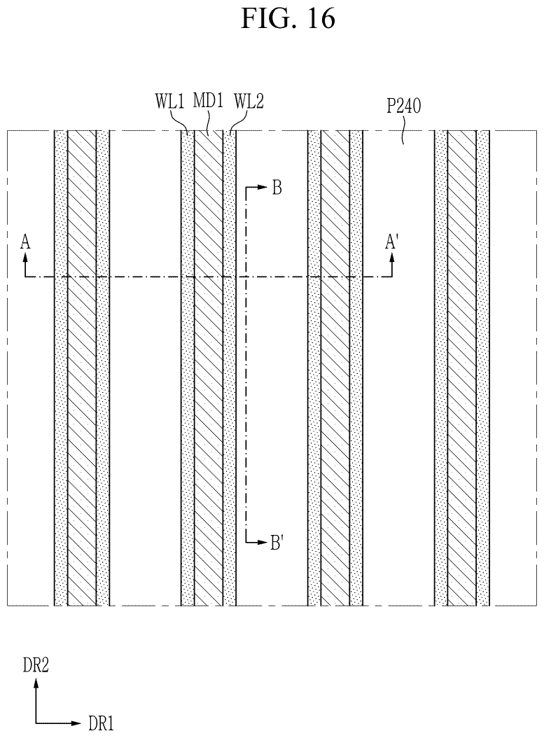

As shown in FIGS. 16 to 18, the first word line WL1 and the second word line WL2 may be formed at opposite sides of the first insulating pattern MD1 by etching the word line material layer PWL. A portion of the word line material layer PWL may be removed through anisotropic etching without using a separate mask. A portion of the word line material layer PWL positioned on the upper surface of the first insulating pattern MD1 and the upper surface of the storage capping material layer P240 may be removed, and a portion of the word line material layer PWL positioned on a side position of the first insulating pattern MD1 may remain. The word line material layer PWL remaining on one side surface, e.g., a left side, of the first insulating pattern MD1 may become the first word line WL1. The remaining word line material layer PWL on the other side, e.g., a right side, of the first insulating pattern MD1 may become the second word line WL2.

The first word line WL1 and the second word line WL2 may extend along the second direction DR2. The first word line WL1 and the second word line WL2 may be spaced apart in the first direction DR1. The first word line WL1 may overlap the first storage contact SC1 in the third direction DR3. The first word line WL1 may overlap the row formed of the first storage contacts SC1 spaced apart along the second direction DR2. The second word line WL2 may overlap the second storage contact SC2 in the third direction DR3. The second word line WL2 may overlap the row formed of the second storage contacts SC2 spaced apart along the second direction DR2.

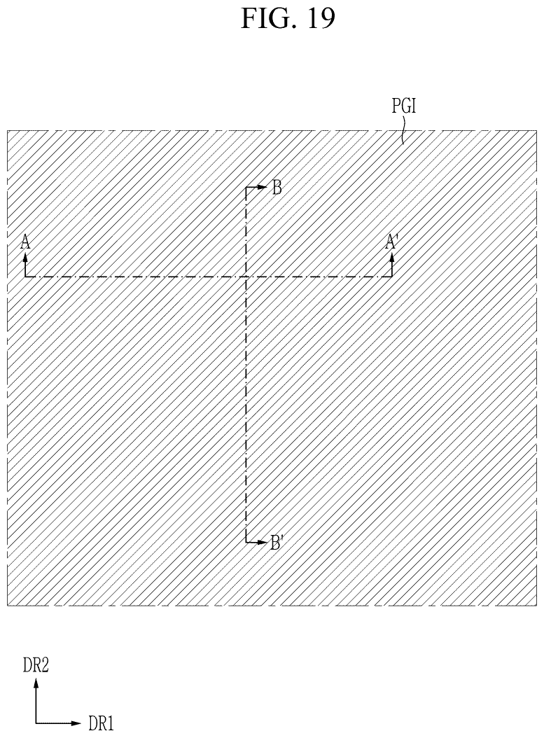

As shown in FIGS. 19 to 21, the gate insulating material layer PG1 may be formed by depositing an insulating material on the first word line WL1 and the second word line WL2. The gate insulating material layer PG1 may be on (e.g., may cover) one side surface and an upper surface of the first word line WL1, one side surface and an upper surface of the second word line WL2, an upper surface of the first insulating pattern MD1, and an upper surface of the storage capping material layer P240. For example, an upper surface and a left-hand side of the first word line WL1 may be covered by the gate insulating material layer PG1, and a right-hand side of the first word line WL1 may be covered by the first insulating pattern MD1. An upper surface and a right-hand side of the second word line WL2 may be covered by the gate insulating material layer PG1, and a left-hand side of the second word line WL2 may be covered by the first insulating pattern MD1. The gate insulating material layer PG1 may be formed conformally. A thickness of the gate insulating material layer PG1 along the third direction DR3 positioned on the upper surface of the first word line WL1, the upper surface of the first insulating pattern MD1, the upper surface of the second word line WL2, and the upper surface of the storage capping material layer P240 may be similar to a thickness of the gate insulating material layer PG1 positioned on the side surface of the first word line WL1 and the side surface of the second word line WL2 along the first direction DR1.

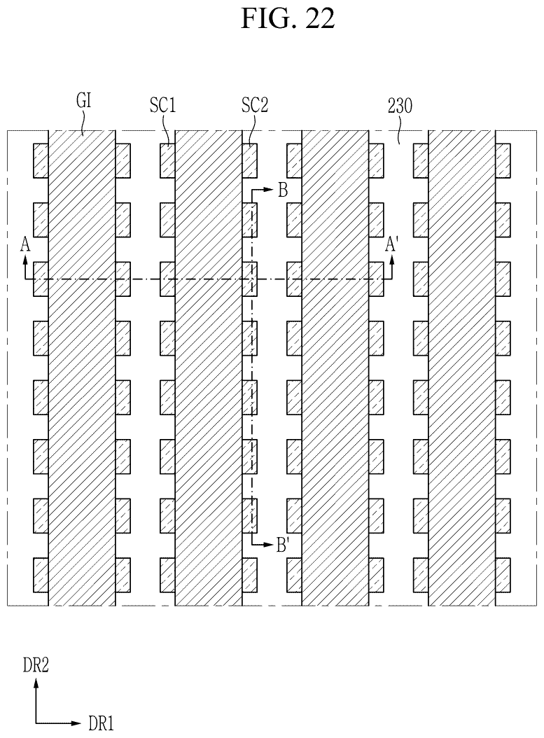

As shown in FIGS. 22 to 24, the gate insulating material layer PG1 may be patterned to form the gate insulating pattern GI on the first word line WL1 and the second word line WL2. A portion of the gate insulating material layer PG1 positioned on the upper surface of the storage capping material layer P240 may be removed, and a portion of the gate insulating material layer PG1 positioned on one side surface and the upper surface of the first word line WL1, one side surface and the upper surface of the second word line WL2, and the upper surface of the first insulating pattern MD1 may remain. The gate insulating pattern GI may be continuously formed to extend on (e.g., to cover) one side surface and an upper surface of the first word line WL1, an upper surface of the first insulating pattern MD1, and an upper surface and one side surface of the second word line WL2.

Next, the storage capping pattern 240 may be formed by etching the storage capping material layer P240 using the gate insulating pattern GI as a mask. A portion of the storage capping pattern 240 that is not covered by the gate insulating pattern GI may be removed, and a portion of the storage capping pattern 240 that is covered by the gate insulating pattern GI may remain. A portion of the upper surface of the first storage contact SC1 and the second storage contact SC2 may be covered by the storage capping pattern 240, and a remaining portion may not be covered by the storage capping pattern 240 and may be exposed to the outside. The storage capping pattern 240 may be on (e.g., may cover) an upper surface of the second interlayer insulating layer 230 positioned between the first storage contact SC1 and the second storage contact SC2. The storage capping pattern 240 may overlap the pair of storage contact rows in the third direction DR3, and may extend along the second direction DR2. The storage capping pattern 240 may not be on (e.g., may not cover) the upper surface of the second interlayer insulating layer 230 positioned between one pair of storage contact rows and another pair of adjacent storage contact rows. A plurality of storage capping patterns 240 may be positioned spaced apart from each other along the first direction DR1.

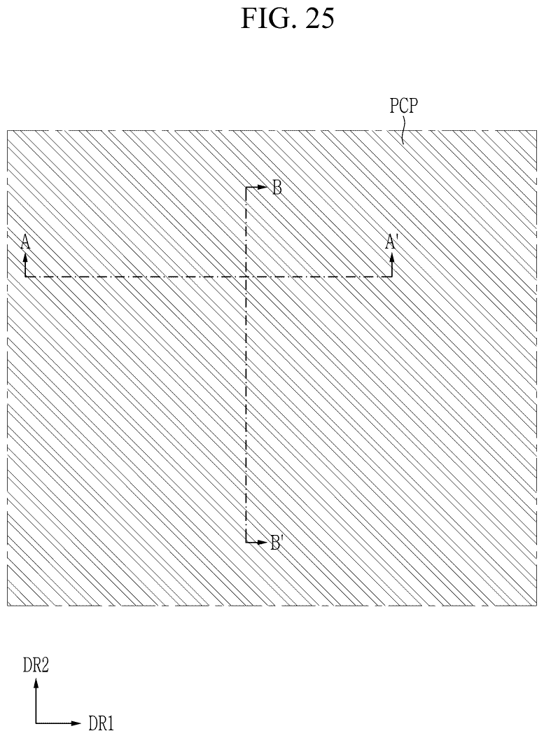

As shown in FIGS. 25 to 27, a channel material layer PCP may be formed by depositing a semiconductor material on the gate insulating pattern GI. The channel material layer PCP may include an oxide semiconductor material. The channel material layer PCP may be formed to surround the gate insulating pattern GI. The channel material layer PCP may be on (e.g., may cover) the side surface of the storage capping pattern 240. The channel material layer PCP may be on (e.g., may cover) exposed portions of the first storage contact SC1, the second storage contact SC2, and the second interlayer insulating layer 230. The channel material layer PCP may be formed conformally.

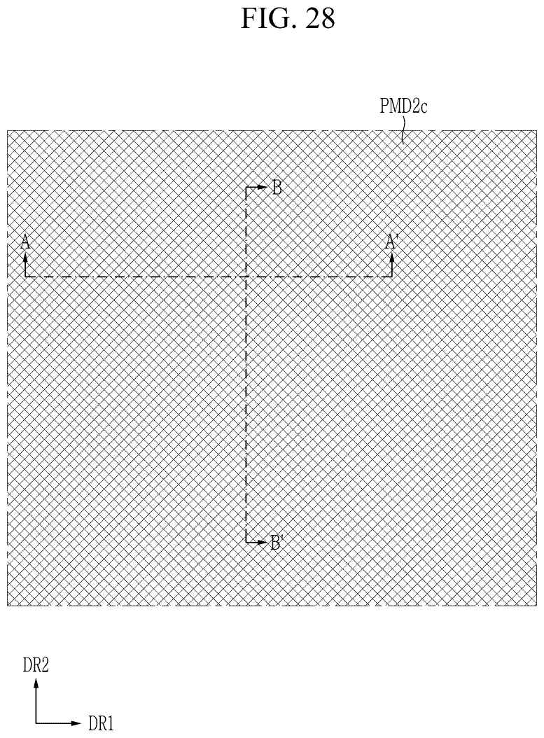

As shown in FIGS. 28 to 30, an insulating material layer PMD2c may be formed by depositing an insulating material on the channel material layer PCP. For example, the insulating liner material layer PMD2c may include silicon oxide. The insulating liner material layer PMD2c may be formed to surround the channel material layer PCP. The insulating liner material layer PMD2c may be formed conformally.

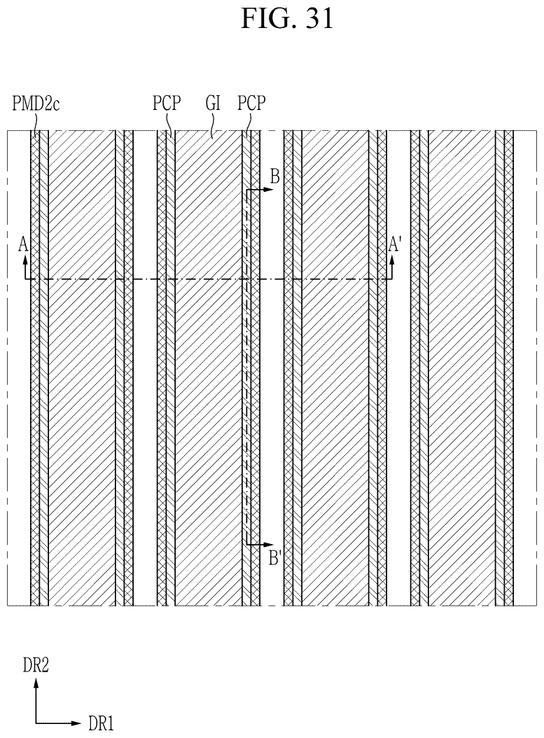

As shown in FIGS. 31 to 33, the insulating liner material layer PMD2c and the channel material layer PCP may be etched to partially remove the insulating liner material layer PMD2c and the channel material layer PCP. The insulating liner material layer PMD2c and the channel material layer PCP may be removed through an anisotropic etching process without using a separate mask. Accordingly, a portion of the insulating liner material layer PMD2c and the channel material layer PCP positioned on the upper surface of the gate insulating pattern GI and the upper surface of the second interlayer insulating layer 230 may be removed, and portions of the insulating liner material layer PMD2c and the channel material layer PCP positioned at opposite sides of the first insulating pattern MD1 may remain.

The remaining insulating liner material layer PMD2c may extend in the second direction DR2, and may be separated to be spaced apart in the first direction DR1. The remaining channel material layer PCP may extend in the second direction DR2, and may be separated apart therefrom in the first direction DR1.

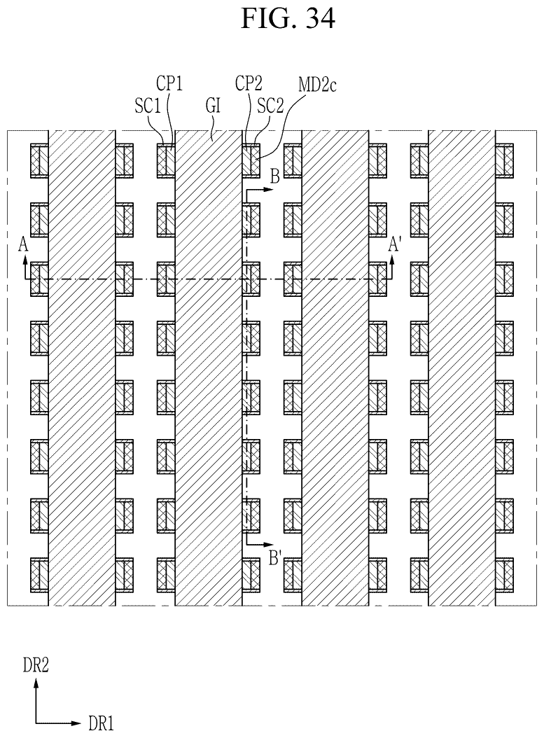

As shown in FIGS. 34 to 36, the insulating liner material layer PMD2c and the channel material layer PCP may be etched to form the insulating liner MD2c, the first channel pattern CP1, and the second channel pattern CP2. In this case, the etching process of the insulating liner material layer PMD2c and the channel material layer PCP may be performed using a separate mask.

The insulating liner material layer PMD2c extending along second direction DR2 may be separated to form a plurality of insulating liner MD2c spaced apart along second direction DR2. A plurality of first channel patterns CP1 spaced apart from each other along the second direction DR2 and a plurality of second channel patterns CP2 spaced apart from each other along the second direction DR2 may be formed by separating the channel material layer PCP extending along the second direction DR2. The first channel pattern CP1 and the second channel pattern CP2 may be spaced apart from each other along the first direction DR1. The channel material layer PCP remaining on one side surface, e.g., a left side surface, of the first insulating pattern MD1 may become the first channel pattern CP1. The remaining channel material layer PCP on the other side surface, e.g., a right side surface, of the first insulating pattern MD1 may become the second channel pattern CP2. The insulating liner material layer PMD2c remaining at opposite sides of the first insulating pattern MD1 may become the insulating liner MD2c.

The gate insulating pattern GI may be positioned between the first channel pattern CP1 and the first word line WL1, and the first channel pattern CP1 may be positioned between the gate insulating pattern GI and the insulating liner MD2c. The gate insulating pattern GI may be located between the second channel pattern CP2 and the second word line WL2, and the second channel pattern CP2 may be positioned between the gate insulating pattern GI and the insulating liner MD2c. The upper surface of the gate insulating pattern GI, the upper surface of the first channel pattern CP1, the upper surface of the second channel pattern CP2, and the upper surface of the insulating liner MD2c may be positioned at substantially a same level (e.g., may be coplanar with each other).

The storage capping pattern 240 may be positioned between the first channel pattern CP1 and the second channel pattern CP2. For example, the first channel pattern CP1 may be positioned at a left side of the storage capping pattern 240, and the second channel pattern CP2 may be positioned at a right side of the storage capping pattern 240.

As shown in FIGS. 2 and 34 to 36, the first channel pattern CP1 and the second channel pattern CP2 may respectively include first vertical portions CP1a and CP2a extending along the third direction DR3, and horizontal portions CP1b and CP2b extending from the first vertical portions CP1a and CP2a. The first vertical portion CP1a of the first channel pattern CP1 may be positioned at one side, e.g., a left side, of the gate insulating pattern GI and the storage capping pattern 240. The horizontal portion CP1b of the first channel pattern CP1 may be positioned on the first storage contact SC1 and the second interlayer insulating layer 230, and may be on (e.g., may cover) a lower surface of the insulating liner MD2c. The horizontal portion CP1b of the first channel pattern CP1 may be in contact with the first storage contact SC1, and may be electrically connected to the first storage contact SC1. The first channel pattern CP1 includes the horizontal portion CP1b, so a contact area with the first storage contact SC1 may be further expanded, reducing contact resistance. The first vertical portion CP2a of the second channel pattern CP2 may be positioned at the other side, e.g., a right side, of the gate insulating pattern GI and the storage capping pattern 240. The horizontal portion CP2b of the second channel pattern CP2 may be positioned on the second storage contact SC2 and the second interlayer insulating layer 230, and may be on (e.g., may cover) a lower surface of the insulating liner MD2c. The horizontal portion CP2b of the second channel pattern CP2 may be in contact with the second storage contact SC2, and may be electrically connected to the second storage contact SC2. The second channel pattern CP2 includes the horizontal portion CP2b, so a contact area with the second storage contact SC2 may be further expanded, reducing contact resistance.

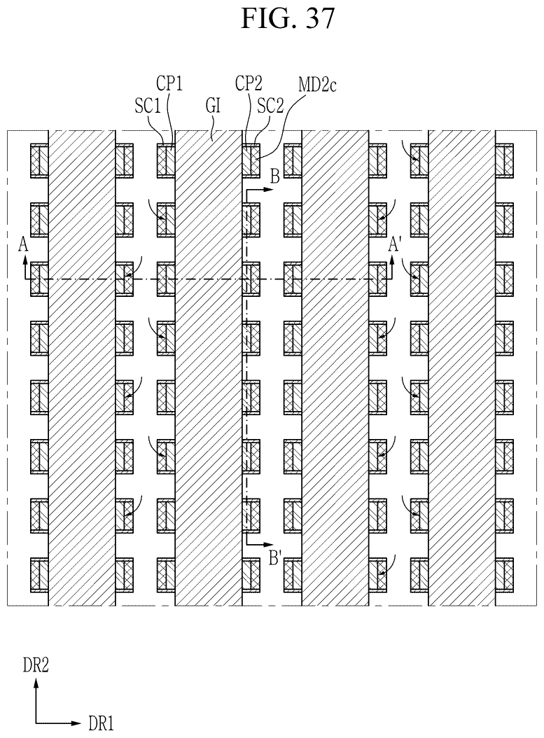

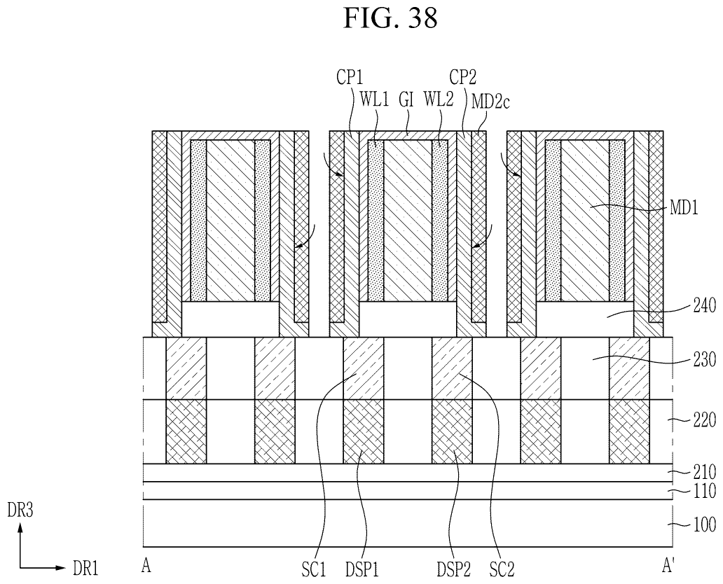

As shown in FIGS. 37 to 39, oxygen may be supplied to the first channel pattern CP1 and the second channel pattern CP2 by performing an annealing process (represented by curved arrows in FIGS. 37 and 38). The first channel pattern CP1 and the second channel pattern CP2 may include an oxide semiconductor material. The insulating liner MD2c on (e.g., covering) the first and second channel patterns CP1 and CP2 may include silicon oxide. When the annealing process is performed, oxygen (e.g., silicon oxide) may be supplied to the first channel pattern CP1 and the second channel pattern CP2 through the insulating liner MD2c made of silicon oxide. The first channel pattern CP1 and the second channel pattern CP2, which have a conductor characteristic, may have a semiconductor characteristic through an annealing process.

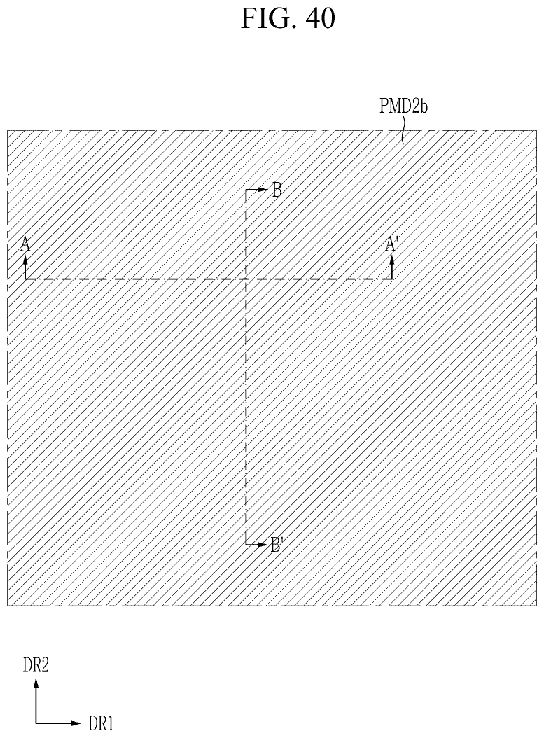

As shown in FIGS. 40 to 42, a capping insulating material layer PMD2b may be formed by depositing an insulating material on the first channel pattern CP1, the second channel pattern CP2, and the insulating liner MD2c. For example, the capping insulating material layer PMD2b may include a high dielectric constant material such as Al₂O₃. The capping insulating material layer PMD2b may be on (e.g., may cover) the upper surface of the gate insulating pattern GI, the upper surface and the side surface of the first channel pattern CP1, the upper surface and the side surface of the second channel pattern CP2, the upper surface and the side surface of the insulating liner MD2c, and the upper surface of the second interlayer insulating layer 230. The capping insulating material layer PMD2b may be formed conformally.

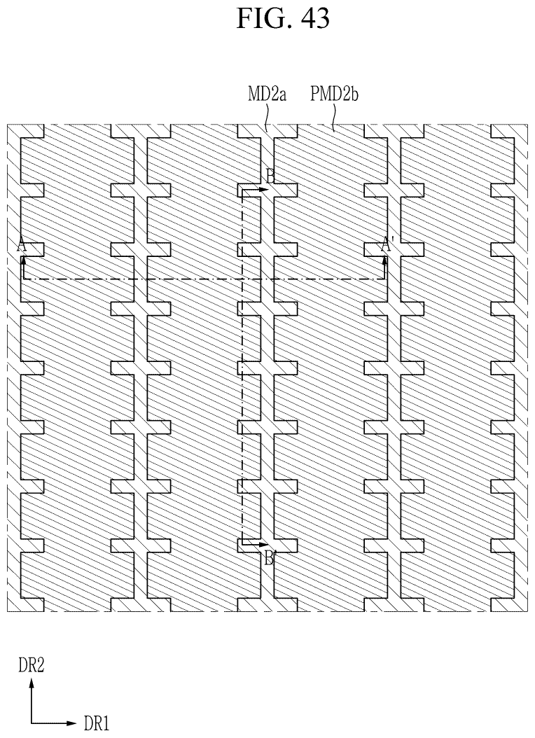

As shown in FIGS. 43 to 45, an insulating material may be deposited on the capping insulating material layer PMD2b, and a planarization process may be performed to form the gap-fill insulating layer MD2a. For example, the gap-fill insulating layer MD2a may include silicon oxide. The gap-fill insulating layer MD2a may be in (e.g., may fill) a space between adjacent first insulating patterns MD1. As a planarization process such as a chemical mechanical polishing process is performed, the upper surface of the gap-fill insulating layer MD2a may be positioned at substantially a same level as (e.g., may be coplanar with) the upper surface of the capping insulating material layer PMD2b. The gap-fill insulating layer MD2a may be surrounded by the capping insulating material layer PMD2b. The capping insulating material layer PMD2b may be on (e.g., may cover) the side surface and the lower surface of the gap-fill insulating layer MD2a.

The gap-fill insulating layer MD2a may include a main pattern portion extending along the second direction DR2, and a plurality of sub-pattern portions branched at opposite sides from the main pattern portion, extending along the first direction DR1, and spaced apart in the second direction DR2 (e.g., see FIG. 43).

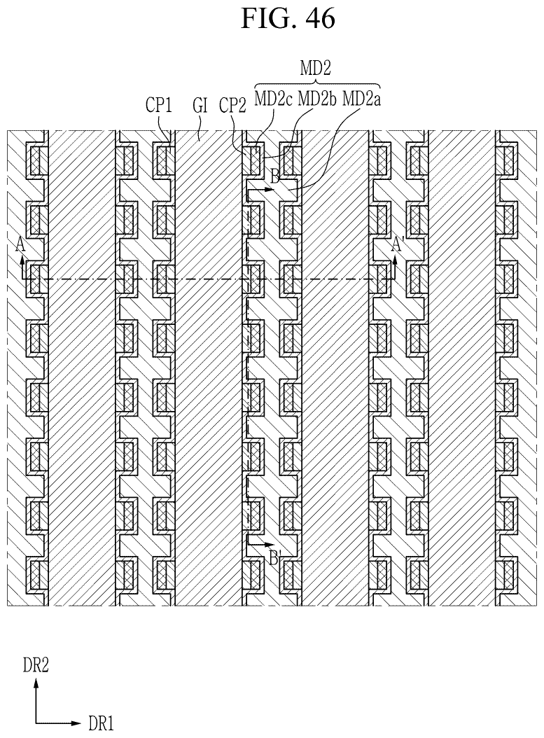

As shown in FIGS. 46 to 48, the capping insulating layer MD2b may be formed by performing an etch-back process to remove a portion of the capping insulating material PMD2b. The gap-fill insulating layer MD2a, the capping insulating layer MD2b, and the insulating liner MD2c may constitute the second insulating pattern MD2. The etch-back process may be performed until the upper surfaces of the first and second channel patterns CP1 and CP2 are exposed. Accordingly, a portion of the capping insulating material layer PMD2b on (e.g., covering) the upper surfaces of the first and second channel patterns CP1 and CP2 may be removed. In this case, a portion of the capping insulating material layer PMD2b on (e.g., covering) the upper surface of the gate insulating pattern GI and the upper surface of the insulating liner MD2c may also be removed. Accordingly, the upper surface of the first channel pattern CP1, the upper surface of the second channel pattern CP2, the upper surface of the gate insulating pattern GI, and the upper surface of the insulating liner MD2c may be exposed to the outside. A portion of the gap-fill insulating layer MD2a may also be etched, and the upper surface of the gap fill insulating layer MD2a may be positioned at substantially a same level as (e.g., may be coplanar with) the upper surface of the capping insulating layer MD2b.

Next, a portion of the insulating liner MD2c may be removed by etching a portion of the insulating liner MD2c. Accordingly, a level of the upper surface of the insulating liner MD2c may be lowered. The upper surface of the insulating liner MD2c may be positioned at a lower level than the upper surfaces of the first and second channel patterns CP1 and CP2. Accordingly, a portion of the side surface of the first channel pattern CP1 may be exposed to the outside, and a portion of the side surface of the second channel pattern CP2 may be exposed to the outside. The upper surface of the insulating liner MD2c may be positioned at a lower level than the upper surfaces of the first and second channel patterns CP1 and CP2. For example, the upper surface of the insulating liner MD2c may be lower than the upper surfaces of the first and second channel patterns CP1 and CP2, with the upper surface of the substrate 100 providing a base reference plane.

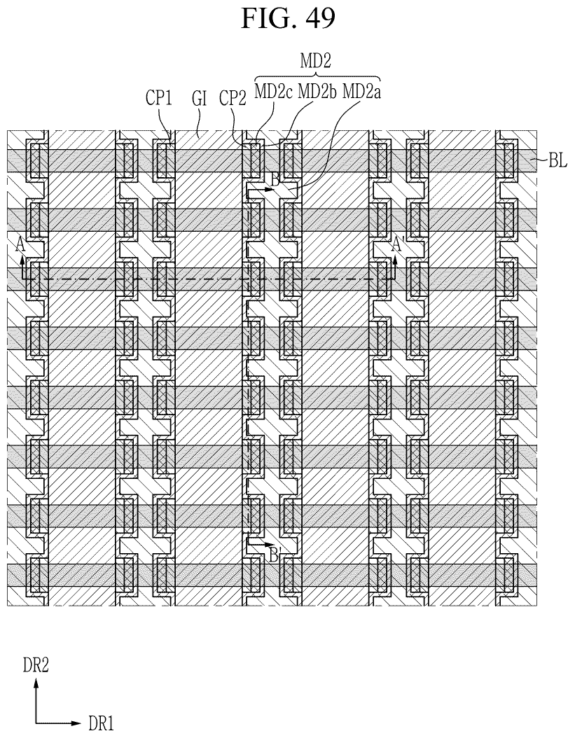

As shown in FIGS. 49 to 51, a conductive material may be deposited on the first channel pattern CP1 and the second channel pattern CP2 and patterned to form a bit line BL. The bit line BL may extend along first direction DR1. A plurality of bit lines BL may be positioned spaced apart along the second direction DR2. Each of the bit lines BL may be connected to a plurality of first channel patterns CP1 and a plurality of second channel patterns CP2 spaced apart from each other along the first direction DR1. The bit line BL may be positioned on the gate insulating pattern GI. The gate insulating pattern GI may be positioned between the bit line BL and the first word line WL1 and between the bit line BL and the second word line WL2.

The bit lines BL may be on (e.g., may cover) upper and side surfaces of the first channel pattern CP1. As a level of the upper surface of the insulating liner MD2c is lowered, an exposed side surface of the first channel pattern CP1 may contact the bit line BL. The bit lines BL may protrude into a space between the first channel pattern CP1 and the capping insulating layer MD2b. As the bit line BL contacts not only the upper surface but also a portion of the side surface of the first channel pattern CP1, a contact area with the first channel pattern CP1 may be expanded, reducing contact resistance. The bit lines BL may be on (e.g., may cover) upper and side surfaces of the second channel pattern CP2. As a level of the upper surface of the insulating liner MD2c is lowered, an exposed side surface of the second channel pattern CP2 may contact the bit line BL. The bit lines BL may protrude into a space between the second channel pattern CP2 and the capping insulating layer MD2b. As the bit line BL contacts not only the upper surface but also a portion of the side surface of the second channel pattern CP2, a contact area with the second channel pattern CP2 may be expanded, reducing contact resistance.

A width of the bit line BL in the second direction DR2 may be smaller than a width of the first channel pattern CP1 in the second direction DR2. The width of the bit line BL in the second direction DR2 may be smaller than a width of the second channel pattern CP2 in the second direction DR2. A distance between adjacent bit lines BL may be sufficiently secured, minimizing interference between the bit lines BL.

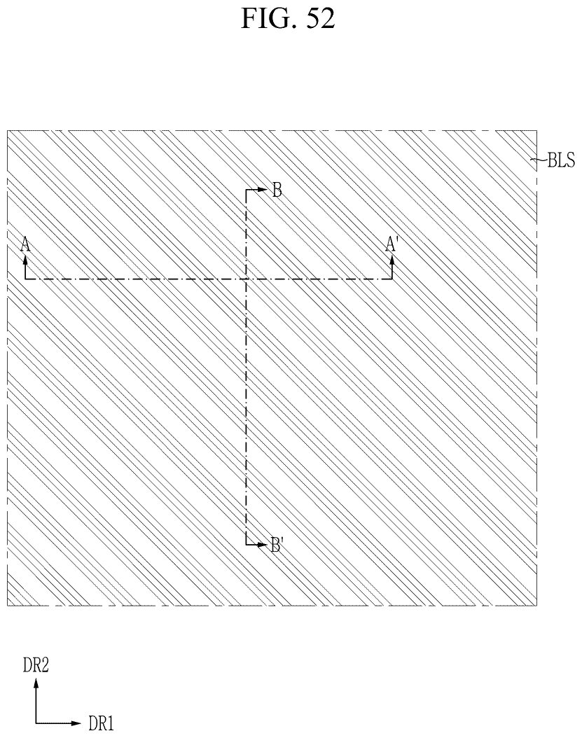

As shown in FIGS. 52 to 54, the bit line capping layer 260 may be formed by depositing an insulating material on the bit line BL. The bit line capping layer 260 may be on (e.g., may cover) upper and side surfaces of the bit line BL. The bit line capping layer 260 may be on (e.g., may cover) the upper surfaces of the gap-fill insulating layer MD2a, the capping insulating layer MD2b, the first channel pattern CP1, and the second channel pattern CP2 between the bit lines BL.

The bit line capping layer 260 may include a lower layer 262 and an upper layer 264. The lower layer 262 of the bit line capping layer 260 may first be disposed on the bit line BL, and then the upper layer 264 of the bit line capping layer 260 may be disposed on the lower layer 262. The lower layer 262 and the upper layer 264 of the bit line capping layer 260 may include different materials. For example, the lower layer 262 may include silicon nitride, and the upper layer 264 may include silicon oxide.

Next, a conductive material may be deposited on the bit line capping layer 260 to form the shield pattern BLS. The shield pattern BLS may be entirely positioned on the bit line capping layer 260. The shield pattern BLS may be spaced apart from the bit line BL by the bit line capping layer 260. The shield pattern BLS may overlap the bit line BL in the second direction DR2 and the third direction DR3.

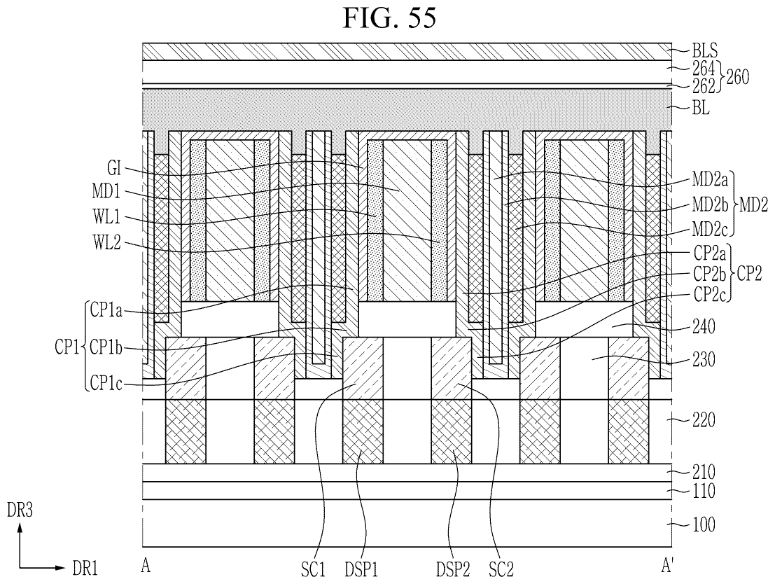

According to some embodiments, a structure and a manufacturing method of the semiconductor device may be changed in various ways, and several modifications will be described below with reference to FIGS. 55 to 59.

FIGS. 55 to 59 each illustrate a cross-sectional view showing a semiconductor device according to some embodiments.

The semiconductor device shown in FIGS. 55 to 59 is similar to the semiconductor device shown in FIGS. 1 to 3, so repeated descriptions may be omitted, and differences will be mainly explained. In addition, same reference numerals are used for same components.

Like the semiconductor device described with reference to FIGS. 1 to 3, the semiconductor device shown in FIGS. 55 to 59 may include a first data storage pattern DSP1 and a second data storage pattern DSP2, a first storage contact SC1 and a second storage contact SC2 connected to the first data storage pattern DSP1 and the second data storage pattern DSP2, respectively, a first word line WL1 and a second word line WL2 positioned on the first storage contact SC1 and the second storage contact SC2, respectively, a first channel pattern CP1 and a second channel pattern CP2 respectively connected to the first storage contact SC1 and the second storage contact SC2, and a bit line BL connected to the first channel pattern CP1 and the second channel pattern CP2. According to some embodiments, the semiconductor device may also further include a first insulating pattern MD1 positioned between the first word line WL1 and the second word line WL2, and a second insulating pattern MD2 positioned between a plurality of first insulating patterns MD1.

As shown in FIG. 55, the first channel pattern CP1 and the second channel pattern CP2 of the semiconductor device according to some embodiments may respectively include first vertical portions CP1a and CP2a extending along the third direction DR3, horizontal portions CP1b and CP2b extending from the first vertical portions CP1a and CP2a, and second vertical portions CP1c and CP2c extending from the horizontal portions CP1b and CP2b along the third direction DR3.

In the semiconductor device described with reference to FIGS. 1 to 3, the first channel pattern CP1 and the second channel pattern CP2 may respectively include first vertical portions CP1a and CP2a and horizontal portions CP1b and CP2b, and in the semiconductor device shown in FIG. 55, the first channel pattern CP1 and the second channel pattern CP2 may further include second vertical portions CP1c and CP2c, respectively.

The first channel pattern CP1 may be electrically connected to the first storage contact SC1. The horizontal portion CP1b of the first channel pattern CP1 may contact the upper surface of the first storage contact SC1, and the second vertical portion CP1c of the first channel pattern CP1 may contact the side surface of the first storage contact SC1. The first channel pattern CP1 includes a second vertical portion CP1c, so a contact area with the first storage contact SC1 may be further expanded. Accordingly, contact resistance between the first channel pattern CP1 and the first storage contact SC1 may be reduced, thereby improving an electric characteristic of the semiconductor device according to embodiments.

The second channel pattern CP2 may be electrically connected to the second storage contact SC2. The horizontal portion CP2b of the second channel pattern CP2 may contact the upper surface of the second storage contact SC2, and the second vertical portion CP2c of the second channel pattern CP2 may contact the side surface of the second storage contact SC2. The second channel pattern CP2 includes a second vertical portion CP2c, so a contact area with the second storage contact SC2 may be further expanded. Accordingly, contact resistance between the second channel pattern CP2 and the second storage contact SC2 may be reduced, thereby improving an electric characteristic of the semiconductor device according to embodiments.

The lower surface of the capping insulating layer MD2b of the second insulating pattern MD2 may be positioned at a similar level to the lower surface of the second vertical portion CP2c of the second channel pattern CP2. For example, the lower surface of the capping insulating layer MD2b may be coplanar with the lower surface of the second vertical portion CP1c of the first channel pattern CP1 and the lower surface of the second vertical portion CP2c of the second channel pattern CP2. The lower surfaces of the gap-fill insulating layer MD2a and capping insulating layer MD2b of the second insulating pattern MD2 may be positioned at a lower level compared to that described with reference to FIGS. 1 to 3. Additionally, the lower surfaces of the first and second channel patterns CP1 and CP2 may be positioned at a lower level compared to that described with reference to FIGS. 1 to 3.

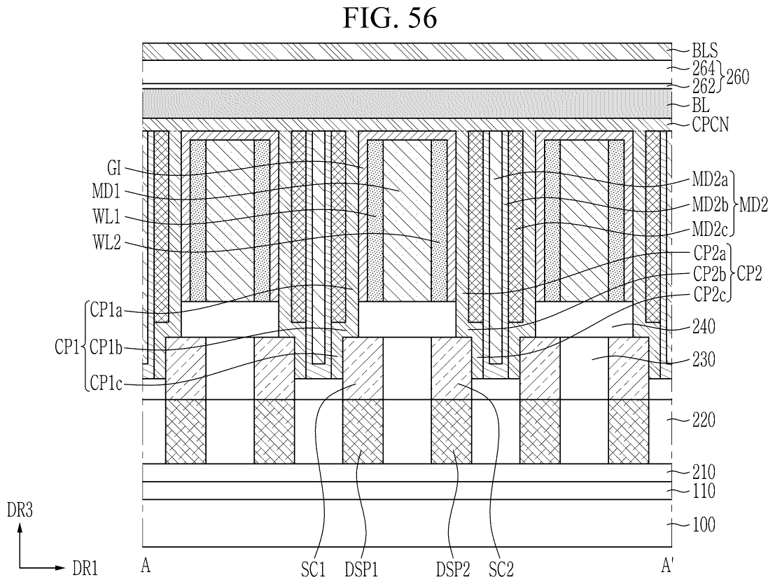

As shown in FIG. 56, the semiconductor device according to some embodiments may further include a channel connection pattern CPCN connecting between the first channel pattern CP1 and the second channel pattern CP2. The channel connection pattern CPCN may be positioned on the first channel pattern CP1 and the second channel pattern CP2. The channel connection pattern CPCN may be in contact with the upper surface of the first channel pattern CP1 and the upper surface of the second channel pattern CP2. The channel connection pattern CPCN may be positioned on the gate insulating pattern GI and the second insulating pattern MD2.

The channel connection pattern CPCN may extend along the first direction DR1. The channel connection pattern CPCN may be positioned below the bit line BL. For example, the channel connection pattern CPCN may extend along the first direction DR1 on a lower surface of the bit line BL. An upper surface of the channel connection pattern CPCN may be in contact with a lower surface of the bit line BL. After the first channel pattern CP1, the second channel pattern CP2, and the second insulating pattern MD2 are formed, a semiconductor material and a conductive material may be sequentially deposited and patterned to form the bit line BL and the channel connection pattern CPCN. In this case, the channel connection pattern CPCN may have a same planar shape as the bit line BL. For example, the channel connection pattern CPCN may include a semiconductor material, but is not limited thereto.

As shown in FIG. 56, an upper surface of the insulating liner MD2c may be positioned at a similar level to the upper surfaces of the first and second channel patterns CP1 and CP2. For example, the upper surface of the insulating liner MD2c may be coplanar with the upper surfaces of the first and second channel patterns CP1 and CP2. However, the present disclosure is not limited thereto, and like the semiconductor device described with reference to FIGS. 1 to 3, the upper surface of the insulating liner MD2c may be positioned at a lower level than the upper surfaces of the first and second channel patterns CP1 and CP2. In this case, the channel connection pattern CPCN may be formed to be on (e.g., to cover) not only the upper surface but also a portion of the side surface of the first channel pattern CP1. In addition, the channel connection pattern CPCN may be formed to be on (e.g., to cover) not only the upper surface but also a portion of the side surface of the second channel pattern CP2.

As shown in FIG. 56, the first channel pattern CP1 and the second channel pattern CP2 may include first vertical portions CP1a and CP2a, horizontal portions CP1b and CP2b, and second vertical portions CP1c and CP2c, respectively. However, the present disclosure is not limited thereto, and the second vertical portions CP1c and CP2c may be omitted, and the first channel pattern CP1 and the second channel pattern CP2 may include first vertical portions CP1a and CP2a and horizontal portions CP1b and CP2b, respectively.

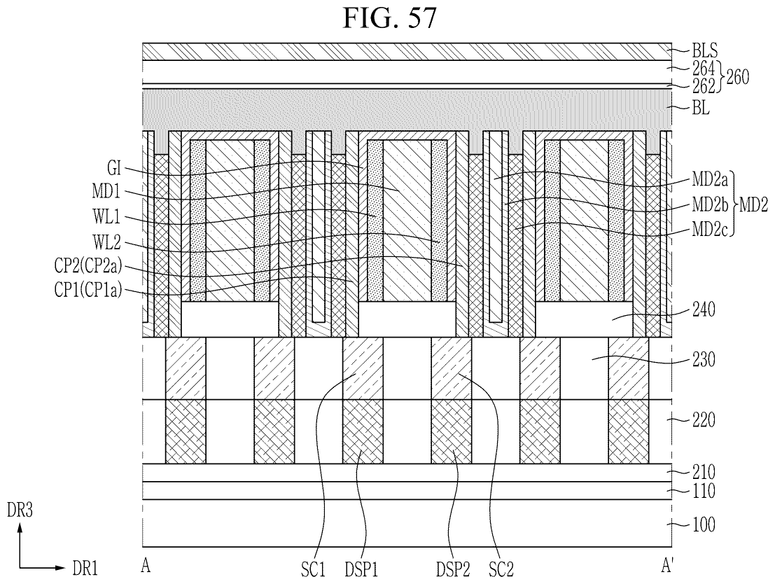

In some embodiments, the horizontal portions CP1b and CP2b may be omitted in the first and second channel patterns CP1 and CP2. As shown in FIG. 57, the first channel pattern CP1 and the second channel pattern CP2 may be formed to include the first vertical portions CP1a and CP2a, respectively. The lower surface of the first channel pattern CP1 may contact the upper surface of the first storage contact SC1, and the lower surface of the second channel pattern CP2 may contact the upper surface of the second storage contact SC2.

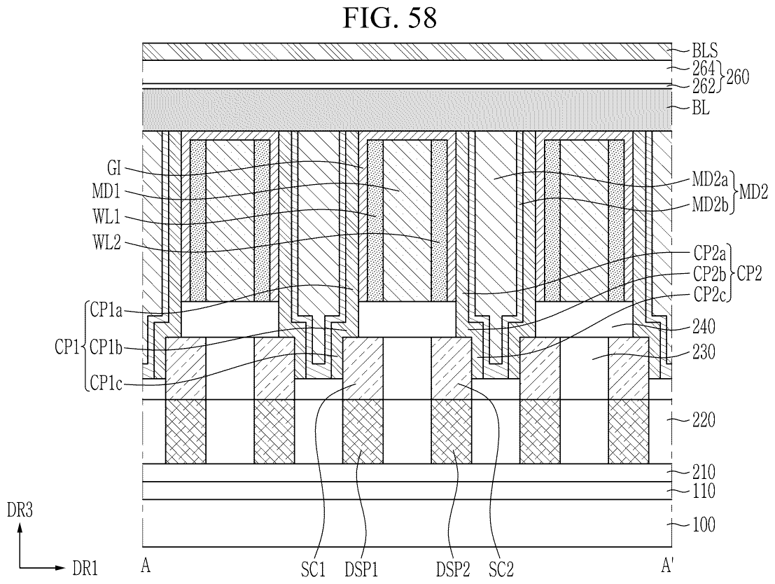

In some embodiments, the insulating liner MD2c may be omitted. As shown in FIG. 58, the second insulating pattern MD2 may include the gap-fill insulating layer MD2a and the capping insulating layer MD2b. In the semiconductor device described with reference to FIGS. 1 to 3, the first channel pattern CP1 and the second channel pattern CP2 may contact the insulating liner MD2c, and in the semiconductor device shown in FIG. 58, the first channel pattern CP1 and the second channel pattern CP2 may be in contact with the capping insulating layer MD2b.

The side surface of the second insulating pattern MD2 may be covered by the first vertical portion CP1a and the second vertical portion CP1c of the first channel pattern CP1, and a portion of the lower surface of the second insulating pattern MD2 may be covered by the horizontal portion CP1b of the first channel pattern CP1, and another portion may not be covered by the first channel pattern CP1. The side surface of the second insulating pattern MD2 may be covered by the first vertical portion CP2a and the second vertical portion CP2c of the second channel pattern CP2, and a portion of the lower surface of the second insulating pattern MD2 may be covered by the horizontal portion CP2b of the second channel pattern CP2, and another portion may not be covered by the second channel pattern CP2.

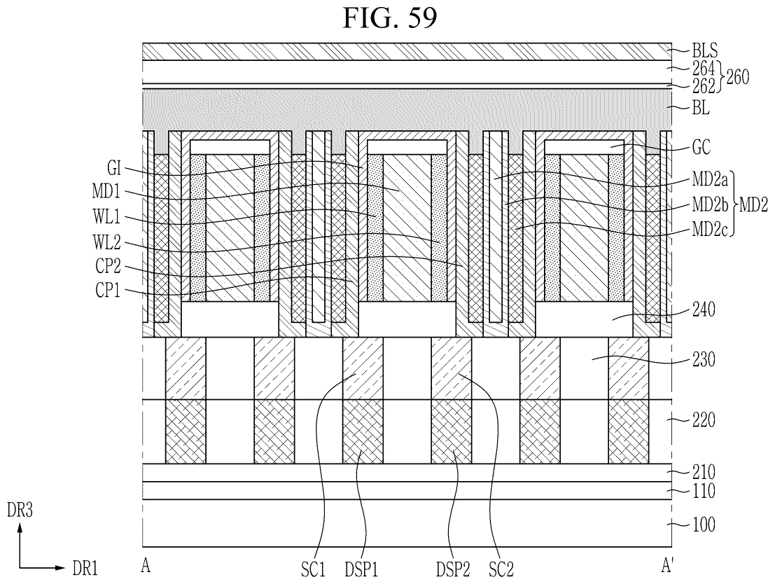

As shown in FIG. 59, the semiconductor device according to some embodiments may further include a gate capping pattern GC positioned on the first word line WL1, the second word line WL2, and the first insulating pattern MD1. The gate capping pattern GC may be on (e.g., may cover) the upper surface of the first word line WL1, the upper surface of the second word line WL2, and the upper surface of the first insulating pattern MD1. The gate insulating pattern GI may be located on the gate capping pattern GC. The upper and side surfaces of the gate capping pattern GC may be covered by the gate insulating pattern GI.

While example embodiments of the present disclosure have been described above with reference to the accompanying drawings, it will be understood that the present disclosure is not limited thereto. Rather, the present disclosure is intended to cover various modifications and equivalent dispositions included within the scope of the appended claims.

What is claimed is:

1. A semiconductor device comprising:
a substrate;
a first data storage pattern and a second data storage pattern spaced apart from each other along a first direction on the substrate;
a first storage contact electrically connected to the first data storage pattern;
a second storage contact electrically connected to the second data storage pattern;
a first word line that extends along a second direction intersecting the first direction and overlaps the first storage contact in a third direction perpendicular to the first and second directions;
a second word line that extends along the second direction and overlaps the second storage contact in the third direction;
a first insulating pattern between the first word line and the second word line;
a first channel pattern electrically connected to the first storage contact;
a second channel pattern electrically connected to the second storage contact;
a bit line that is electrically connected to the first channel pattern and the second channel pattern and extends along the first direction; and
a gate insulating pattern between the first word line and the first channel pattern, between the second word line and the second channel pattern, between the first word line and the bit line, between the second word line and the bit line, and between the first insulating pattern and the bit line.

2. The semiconductor device of claim 1, wherein the gate insulating pattern continuously extends on a side surface and an upper surface of the first word line, an upper surface of the first insulating pattern, and an upper surface and a side surface of the second word line,
wherein an upper surface of the gate insulating pattern, an upper surface of the first channel pattern, and an upper surface of the second channel pattern are coplanar,
wherein a width of the bit line in the second direction is smaller than a width of the first channel pattern in the second direction, and
wherein the width of the bit line in the second direction is smaller than a width of the second channel pattern in the second direction.

3. The semiconductor device of claim 1, further comprising a second insulating pattern adjacent to the first insulating pattern along the first direction,
wherein the second insulating pattern comprises:
a gap-fill insulating layer; and
a capping insulating layer on a side surface and a lower surface of the gap-fill insulating layer.

4. The semiconductor device of claim 3, wherein the second insulating pattern further comprises an insulating liner on opposite sides of the capping insulating layer, and
wherein the insulating liner is between the first channel pattern and the capping insulating layer and between the second channel pattern and the capping insulating layer.

5. The semiconductor device of claim 4, wherein an upper surface of the insulating liner is lower than an upper surface of the first channel pattern and an upper surface of the second channel pattern, with an upper surface of the substrate providing a base reference plane, and
wherein the bit line is on the upper surface and a side surface of the first channel pattern and the upper surface and a side surface of the second channel pattern.

6. The semiconductor device of claim 5, wherein the upper surface of the insulating liner is lower than an upper surface of the gap-fill insulating layer and an upper surface of the capping insulating layer, with the upper surface of the substrate providing a base reference plane, and
wherein the bit line is between the first channel pattern and the capping insulating layer and between the second channel pattern and the capping insulating layer.

7. The semiconductor device of claim 3, wherein each of the first channel pattern and the second channel pattern comprises:
a first vertical portion extending between the gate insulating pattern and the second insulating pattern in the third direction; and
a horizontal portion extending from the first vertical portion and on a lower surface of the second insulating pattern.

8. The semiconductor device of claim 7, wherein the second insulating pattern further comprises an insulating liner on opposite sides of the capping insulating layer, and
wherein the horizontal portion is on a lower surface of the insulating liner.

9. The semiconductor device of claim 7, wherein each of the first channel pattern and the second channel pattern further comprises a second vertical portion extending from the horizontal portion in the third direction,
wherein the horizontal portion and the second vertical portion of the first channel pattern contact an upper surface and a side surface of the first storage contact, respectively, and
wherein the horizontal portion and the second vertical portion of the second channel pattern contact an upper surface and a side surface of the second storage contact, respectively.

10. The semiconductor device of claim 7, wherein the first channel pattern and the second channel pattern are in contact with the capping insulating layer.

11. The semiconductor device of claim 1, further comprising:
a first bonding insulating layer on the substrate; and
a second bonding insulating layer bonded to the first bonding insulating layer,
wherein the first data storage pattern and the second data storage pattern are on the second bonding insulating layer.

12. The semiconductor device of claim 1, wherein an upper surface of the first data storage pattern is in contact with a lower surface of the first storage contact, and
wherein an upper surface of the second data storage pattern is in contact with a lower surface of the second storage contact.

13. The semiconductor device of claim 1, wherein the bit line is a first bit line,
wherein the semiconductor device further comprises:
a second bit line adjacent to the first bit line along the second direction;
a bit line capping layer on the first bit line and the second bit line; and
a shield pattern on the bit line capping layer, and
wherein the shield pattern is between the first bit line and the second bit line.

14. The semiconductor device of claim 1, further comprising a channel connection pattern on the first channel pattern and the second channel pattern,
wherein the channel connection pattern extends along the first direction on a lower surface of the bit line.

15. The semiconductor device of claim 1, further comprising a gate capping pattern on the first word line, the second word line, and the first insulating pattern,
wherein the gate insulating pattern is on an upper surface and opposing side surfaces of the gate capping pattern.

16. The semiconductor device of claim 1, further comprising a storage capping pattern on the first storage contact and the second storage contact,
wherein the first word line, the second word line, the first insulating pattern, and the gate insulating pattern are on the storage capping pattern.

17. A semiconductor device comprising:
a substrate;
a first data storage pattern and a second data storage pattern spaced apart from each other along a first direction on the substrate;
a first storage contact in contact with an upper surface of the first data storage pattern;
a second storage contact in contact with an upper surface of the second data storage pattern;
a first word line spaced apart from the first storage contact and extending along a second direction intersecting the first direction;
a second word line spaced apart from the second storage contact and extending along the second direction;
a first insulating pattern between the first word line and the second word line;
a gate insulating pattern on a side surface and an upper surface of the first word line, an upper surface of the first insulating pattern, and an upper surface and a side surface of the second word line;
a first channel pattern spaced apart from the first word line, with the gate insulating pattern therebetween, and electrically connected to the first storage contact;
a second channel pattern spaced apart from the second word line, with the gate insulating pattern therebetween, and electrically connected to the second storage contact; and
a bit line that contacts an upper surface and a side surface of the first channel pattern and an upper surface and a side surface of the second channel pattern, the bit line extending along the first direction.

18. The semiconductor device of claim 17, further comprising a second insulating pattern adjacent to the first insulating pattern along the first direction,
wherein the second insulating pattern comprises:
a gap-fill insulating layer;
a capping insulating layer on a side surface and a lower surface of the gap-fill insulating layer; and
an insulating liner on opposite sides of the capping insulating layer, and
wherein an upper surface of the insulating liner is lower than the upper surface of the first channel pattern, the upper surface of the second channel pattern, an upper surface of the gap-fill insulating layer, and an upper surface of the capping insulating layer, with an upper surface of the substrate providing a base reference plane.

19. A semiconductor device comprising:
a substrate;
a first data storage pattern and a second data storage pattern spaced apart from each other along a first direction on the substrate;
a first storage contact in contact with an upper surface of the first data storage pattern;
a second storage contact in contact with an upper surface of the second data storage pattern;
a first word line spaced apart from the first storage contact and extending along a second direction intersecting the first direction;
a second word line spaced apart from the second storage contact and extending along the second direction;
a first insulating pattern between the first word line and the second word line;
a gate insulating pattern on a side surface and an upper surface of the first word line, an upper surface of the first insulating pattern, and an upper surface and a side surface of the second word line;
a first channel pattern spaced apart from the first word line, with the gate insulating pattern therebetween, and on an upper surface and a side surface of the first storage contact;
a second channel pattern spaced apart from the second word line, with the gate insulating pattern therebetween, and on an upper surface and a side surface of the second storage contact; and
a bit line electrically connected to the first channel pattern and the second channel pattern and extending along the first direction.

20. The semiconductor device of claim 19, further comprising a second insulating pattern adjacent to the first insulating pattern along the first direction,
wherein each of the first channel pattern and the second channel pattern comprises:
a first vertical portion extending between the gate insulating pattern and the second insulating pattern in a third direction perpendicular to the first and second directions;
a horizontal portion extending from the first vertical portion and on a lower surface of the second insulating pattern; and
a second vertical portion extending from the horizontal portion in the third direction,
wherein the horizontal portion and the second vertical portion of the first channel pattern contact the upper surface and the side surface of the first storage contact, respectively, and
wherein the horizontal portion and the second vertical portion of the second channel pattern contact the upper surface and the side surface of the second storage contact, respectively.
